(19) United States
(12) Patent Application Publication
(10) Pub. No.: US 2011/0281040 A1
(43) Pub. Date: Nov. 17, 2011

(54) LIQUID CRYSTAL DISPLAY ELEMENT, POSITIVE TYPE RADIATION SENSITIVE COMPOSITION, INTERLAYER INSULATING FILM FOR LIQUID CRYSTAL DISPLAY ELEMENT, AND FORMATION METHOD THEREOF

(75) Inventors: Daigo ICHINOHE, Tokyo (JP); Mika Nakayama, Tokyo (JP)

(73) Assignee: JSR CORPORATION, Tokyo (JP)

(21) Appl. No.: 13/107,442

(22) Filed: May 13, 2011

(30) Foreign Application Priority Data
May 14, 2010 (JP) 2010-112698
Feb. 18, 2011 (JP) 2011-33784

(51) Int. Cl. G09F 9/35; G03F 7/40; C09K 19/52; G03F 7/039

(52) U.S. Cl. 428/1.54; 430/280.1; 430/326

(57) ABSTRACT

Provided by the present invention is a liquid crystal display element including:
two substrates disposed oppositely,
   an interlayer insulating film laminated on the inner face side of at least one of the substrates, and
   a liquid crystal layer being provided between the substrates, and being formed from a polymerizable liquid crystal composition, in which
   a resin constituting the interlayer insulating film has a crosslinking moiety of a polymer represented by the following formula (1):

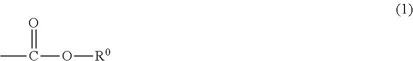

### TECHNICAL FIELD

The present invention relates to a liquid crystal display element, a positive type radiation sensitive composition, an interlayer insulating film for a liquid crystal display element and a formation method of the same.

### BACKGROUND ART

In recent years, liquid crystal display devices have been widely used as TV receivers, monitoring devices of personal computers, and the like. For the liquid crystal display devices used in these applications, large viewing angle that makes a display screen be visible from any directions has been desired. As exemplary liquid crystal display devices that can achieve a large viewing angle, those in which a liquid crystal display element of a MVA (Multi-domain Vertical Alignment) system have been known. However, such liquid crystal display devices cannot attain a sufficiently short response time of liquid crystals, and are disadvantageous in that disturbance of alignment due to pressing with finger, and the like, is likely to occur.

Thus, introduction of a PSA (Polymer Sustained Alignment) technique into liquid crystal display element to permit memorizing the tilt direction of liquid crystal compounds by: blending a polymerizable monomer by light or heat in liquid crystals; and applying a voltage to polymerize the monomer in the state in which the liquid crystal compounds are tilted has been investigated (see JP-A No. 2003-149647). Liquid crystal display elements produced using the PSA technique have a potent alignment-restraining force since a polymerized film that memorized the tilt direction of liquid crystal compounds is formed on the interface between the liquid crystals and the aligned film. Therefore, by using this PSA technique, a liquid crystal display device having a short response time of liquid crystals, and being less likely to be accompanied by disturbance of alignment even if pressed with finger, and the like can be realized.

In such a liquid crystal display element produced using the PSA technique, a liquid crystal containing a monomer that is reactable by light or heat is injected between a pair of substrates, and thereafter the cell in its entirety is subjected to light irradiation or heating, whereby polymerization of the monomer is permitted. Thus, according to this liquid crystal display element, the interlayer insulating film laminated on a substrate may be deformed by the light or heat for allowing the liquid crystals to react. When the interlayer insulating film is deformed, for example, the voltage holding ratio of the liquid crystal display element may be lowered.

On the other hand, the applicant of the present application developed an interlayer insulating film having a high hardness by using a positive type radiation sensitive composition containing a polymer having a carboxyl group and an epoxy group in one molecule to highly form a crosslinked structure by a thermal curing reaction of the carboxyl group and the epoxy group (see JP-A No. H05-165214).

In this positive type radiation sensitive composition, when the content of the carboxyl group and the epoxy group in the polymer increases, an interlayer insulating film can be obtained which is superior in heat resistance and light resistance and can endure production of liquid crystal display elements using the PSA technique. However, increased content of highly reactive carboxyl group and epoxy group in the polymer may deteriorate storage stability of the radiation sensitive composition, and may be thus disadvantageous in that productivity of the liquid crystal display element may be impaired.

### PRIOR ART DOCUMENTS

### Patent Documents

Patent Document 1: JP-A No. 2003-149647
Patent Document 2: JP-A No. H05-165214

### SUMMARY OF THE INVENTION

### Problems to be Solved by the Invention

The present invention was made in view of the foregoing circumstances, and an object of the invention is to provide a liquid crystal display element having a high voltage holding ratio, and being provided with an interlayer insulating film having superior heat resistance and light resistance, and to also provide a positive type radiation sensitive composition that is superior in storage stability, and is suited for formation of the interlayer insulating film.

### Means for Solving the Problems

An aspect of the invention made for solving the aforementioned problems is a liquid crystal display element comprising:

two substrates disposed oppositely,
an interlayer insulating film laminated on the inner face side of at least one of the substrates, and
a liquid crystal layer being provided between the substrates, and being formed from a polymerizable liquid crystal composition, wherein
a resin constituting the interlayer insulating film has a crosslinking moiety of a polymer represented by the following formula (1):

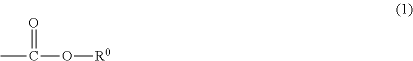

wherein, R⁰ is a group represented by the following formulae (1-1) to (1-6).

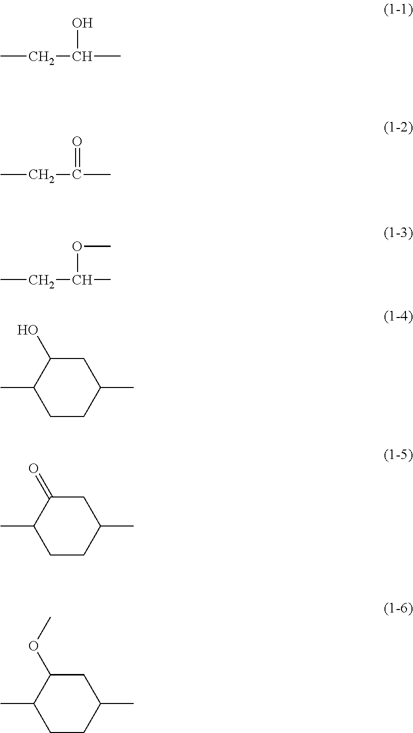

Due to the resin that constituted the liquid crystal display element of the present invention having an interlayer insulating film having a crosslinking moiety of the polymer represented by the above formula (1), providing superior heat resistance and light resistance is enabled, and as a consequence, the liquid crystal display element can have a high voltage holding ratio.

In the liquid crystal display element, the interlayer insulating film is formed using a positive type radiation sensitive composition containing:

(A) a polymer (hereinafter, may also referred to as “polymer (A)”) having a structure unit (hereinafter, may be also referred to as “structure unit (1)”) including a group represented by the following formula (2) and an epoxy group-containing structure unit in the same or different polymer molecules;

(B) a photoacid generator; and

(C) an organic solvent.

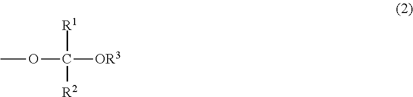

wherein, R¹ and R² each independently represent a hydrogen atom, an alkyl group, a cycloalkyl group or an aryl group, and a part or all of hydrogen atoms of the alkyl group, the cycloalkyl group or the aryl group may be substituted; both R¹ and R² are not concomitantly a hydrogen atom; R³ is an alkyl group, a cycloalkyl group, an aralkyl group, an aryl group or a group represented by -M (R^{3 m})₃, wherein M is Si, Ge or Sn. R^{3 m} is an alkyl group, and a part or all of hydrogen atoms of these groups may be substituted; and R¹ and R³ may link to form a cyclic ether.

Since a functional group, which reacts with an epoxy group, of the polymer (A) is protected by a structure represented by the above formula (2), it does not react in a normal state, and a reaction of the functional group and the epoxy group does not start until deprotected with an acid. Therefore, the positive type radiation sensitive composition that contains the polymer (A) is superior in storage stability, and the liquid crystal display element has high productivity. Also, since the interlayer insulating film of the liquid crystal display element is firmly hardened by a crosslinking reaction of the deprotected functional group with the epoxy group, providing superior heat resistance and light resistance is enabled, and as a consequence, the liquid crystal display element can have a high voltage holding ratio.

The polymerizable liquid crystal composition preferably has photopolymerizability or thermal polymerizability. Since the polymerizable liquid crystal composition has photopolymerizability or thermal polymerizability, a liquid crystal layer can be formed from a polymerizable liquid crystal composition by irradiation of light or heating, whereby efficient production is enabled. In addition, according to the liquid crystal display element, deformation and the like of the interlayer insulating film is suppressed even if the element is produced via such irradiation of light or heating; therefore, a high voltage holding ratio and superior productivity can be achieved.

The positive type radiation sensitive composition of the present invention is used for forming an interlayer insulating film of a liquid crystal display element provided with:

two substrates disposed oppositely;
an interlayer insulating film laminated on the inner face side of at least one of the substrates; and
a liquid crystal layer being provided between the substrates, and being formed from a polymerizable liquid crystal composition,
the positive type radiation sensitive composition comprising:
   (A) a polymer having a structure unit including a group represented by the following formula (2) and an epoxy group-containing structure unit in the same or different polymer molecules;
   (B) a photoacid generator; and
   (C) an organic solvent.

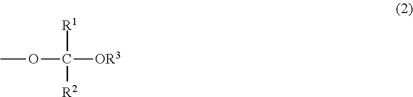

wherein, R¹ and R² each independently represent a hydrogen atom, an alkyl group, a cycloalkyl group or an aryl group, and a part or all of hydrogen atoms of the alkyl group, the cycloalkyl group or the aryl group may be substituted; both R¹ and R² are not concomitantly a hydrogen atom; R³ is an alkyl group, a cycloalkyl group, an aralkyl group, an aryl group or a group represented by -M (R^{3 m})₃, wherein M is Si, Ge or Sn; R^{3 m} is an alkyl group, and a part or all of hydrogen atoms of these groups may be substituted; and R¹ and R³ may link to form a cyclic ether.

Since a functional group that reacts with the epoxy group in the polymer (A) is protected by the structure represented by the above formula (2) as described above, the reaction does not occur in common states, and the reaction of the epoxy group and the functional group will be allowed upon deprotection by an acid. Irradiation with a radioactive ray allows a crosslinking reaction of the deprotected functional group with the epoxy group to proceed, thereby permitting rigid curing. Accordingly, an interlayer insulating film that is superior in heat resistance and light resistance can be obtained, and superior storage stability is achieved. Thus, the positive type radiation sensitive composition can suitably form an interlayer insulating film for a liquid crystal display element in which a liquid crystal layer is formed by heat or light irradiation.

The positive type radiation sensitive composition further comprising (D) a surfactant, and this surfactant (D) is preferably a silicone based surfactant. The positive type radiation sensitive composition can improve the uniformity of film thickness of the interlayer insulating film obtained by further including a silicone based surfactant. As a result, the voltage holding ratio of the resultant liquid crystal display element can be further improved.

The method for forming an interlayer insulating film for a liquid crystal display element of the present invention has the steps of:

(1) forming a coated film of the positive type radiation sensitive composition on a substrate;

(2) irradiating at least a part of the coated film formed in the step (1) with a radioactive ray;

(3) developing the coated film irradiated with a radioactive ray in the step (2); and

(4) heating the coated film developed in the step (3).

The method for forming is suited as a formation method of an interlayer insulating film for a liquid crystal display element in which a liquid crystal layer is formed by heat or light irradiation.

The interlayer insulating film for a liquid crystal display element of the present invention is formed using the aforementioned positive type radiation sensitive composition. The interlayer insulating film can be, as described above, suitably used as an interlayer insulating film for a liquid crystal display element in which a liquid crystal layer is formed by heat or light irradiation.

It is to be noted that the term “polymer” of the component (A) as referred to herein implies a conception including also polymers having the structure unit (1) in one polymer molecule, and having an epoxy group-containing structure unit in a polymer molecule that is different from the one polymer molecule. Also, the conception of the term “radioactive ray” involves visible light ray, ultraviolet ray, far ultraviolet ray, X ray, charged particle ray, and the like.

### Effects of the Invention

As explained in the foregoing, since the interlayer insulating film of the liquid crystal display element of the present invention has a superior heat resistance and light resistance, deformation and the like in the production step can be suppressed, and consequently the liquid crystal display element of the present invention can achieve a superior voltage retaining capacity. In addition, since the positive type radiation sensitive composition is superior in storage stability, high productivity of the liquid crystal display element is provided.

### BRIEF DESCRIPTION OF THE DRAWINGS

FIG. 1 shows a schematic cross sectional view illustrating a state during production of a liquid crystal display element according to one embodiment of the liquid crystal display element of the present invention.

### MODE FOR CARRYING OUT THE INVENTION

The liquid crystal display element of the present invention has two substrates disposed oppositely, an interlayer insulating film laminated on the inner face side of at least one of the substrates, and a liquid crystal layer provided between the substrates. Hereinafter, each constitutive element is explained in detail.

### <Substrate>

As the substrate, any one commonly used in general liquid crystal display elements may be exemplified. The material entity of the substrate may include, for example, glass, quartz, silicone, a resin, and the like. The resin may include, for example, polyethylene terephthalate, polybutylene terephthalate, polyethersulfone, polycarbonate, polyimide, a ring-opened polymer of a cyclic olefin and a hydrogenated product thereof, and the like. It should be noted that this substrate is not limited to a hard material entity, and may be a material entity having flexibility such as a plastic film.

At least one of the substrates disposed oppositely has transparency. The liquid crystal layer becomes visible from the external side through the substrate having transparency. Also, in the case in which the liquid crystal display element is used for acting on light that passes from one side to another side of the element, two substrates both should have transparency. This substrate may be provided with a transparent or opaque electrode disposed on the entire face or partial face to meet the object. In addition, a spacer for maintaining an interval may be present, in general, between the two substrates, similarly to well-known liquid crystal display elements.

### <Interlayer Insulating Film>

The interlayer insulating film is formed using (A) a polymer, (B) a photoacid generator and (C) a positive type radiation sensitive composition containing an organic solvent, and the resin constituting the interlayer insulating film has a crosslinking moiety of the polymer represented by the above formula (1). Since the liquid crystal display element is provided with the interlayer insulating film having a crosslinking moiety, which is a group represented by the above formula (1), of the polymer, providing superior heat resistance and light resistance is enabled, and as a consequence, the liquid crystal display element can have a high voltage holding ratio.

In the above formula (1), R⁰ is a group represented by any one of the above formulae (1-1) to (1-6).

The crosslinking moiety of the polymer represented by the above formula (1) is formed by, for example, thermal crosslinking of a polymer having a functional group such as a carboxyl group with a polymer having an epoxy group as represented by the following reaction formula, or thermal crosslinking of molecules of a polymer having a carboxyl group and an epoxy group in one molecule. The functional group such as a carboxyl group described above may include, for example, a group derived by deprotection with an acid of a protecting group represented by the above formula (2).

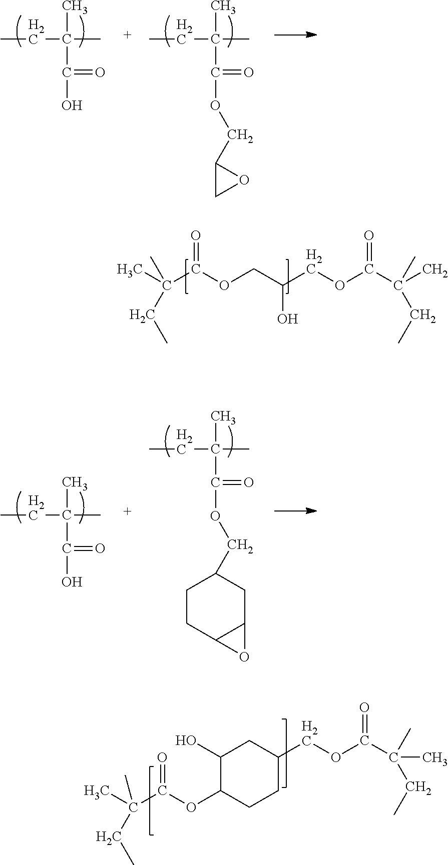

In addition, the positive type radiation sensitive composition may further contain other arbitrary component. Hereinafter, each component of the positive type radiation sensitive composition is described in detail.

### [Polymer (A)]

The polymer (A) has the aforementioned structure unit (1) and the epoxy group-containing structure unit in the same or different polymer molecule(s), and may have additional other structure unit as needed. Since the polymer (A) has a functional group that reacts with the epoxy group, which functional group being protected by a structure represented by the above formula (2), it does not react in a usual state, and the reaction of the functional group and the epoxy group is initiated by deprotection with an acid. Therefore, the positive type radiation sensitive composition including the polymer (A) is superior in storage stability, and the liquid crystal display element has high productivity. Additionally, since the interlayer insulating film of the liquid crystal display element is rigidly cured by a crosslinking reaction of the deprotected functional group and the epoxy group, providing superior heat resistance and light resistance is enabled, and as a consequence, the liquid crystal display element can have a high voltage holding ratio.

Embodiments of the polymer (A) having the structure unit (1) and the epoxy group-containing structure unit are not particularly limited, and may include

(i) those having both the structure unit (1) and the epoxy group-containing structure unit in an identical polymer molecule, and thus one kind of a polymer molecule is present in the polymer (A);

(ii) those having one the structure unit (1) in one polymer molecule, and having the epoxy group-containing structure unit in a polymer molecule distinct from the former polymer molecule, and thus two kinds of polymer molecules are present in the polymer (A);

(iii) those having both the structure unit (1) and the epoxy group-containing structure unit in one polymer molecule, further having the structure unit (1) in a polymer molecule distinct from the former polymer molecule and still further having the epoxy group-containing structure unit in another polymer molecule distinct from the former polymer molecules, and thus three kinds of polymer molecules are present in the polymer (A);

(iv) those including in addition to the polymer molecules defined in the above (i) to (iii), one or two or more kinds of other polymer molecules in the polymer (A), and the like.

### (Structure Unit (1))

In the structure unit (1), since the group represented by the above formula (2) is present as a group that generates a polar group by dissociation in the presence of an acid (hereinafter, may also referred to as “acid-dissociable group”), an acid generated from a photoacid generator by irradiation of a radioactive ray allows the acid-dissociable group to be dissociated, and as result, the polymer (A) which was alkali-insoluble becomes alkali-soluble. The aforementioned acid-dissociable group has an acetal structure or a ketal structure that is comparatively stable against alkali, and thus this leads to dissociation by the action of the acid.

In the above formula (2), the alkyl group represented by R¹ and R² is preferably a linear and branched alkyl group having 1 to 30 carbon atoms. An oxygen atom, a sulfur atom, nitrogen atom may be included in the alkyl chain. Examples of the alkyl group include linear alkyl groups such as a methyl group, an ethyl group, a n-propyl group, a n-butyl group, a n-pentyl group, a n-hexyl group, a n-octyl group, a n-dodecyl group, a n-tetradecyl group and a n-octadecyl group, branched alkyl groups such as an i-propyl group, an i-butyl group, a t-butyl group, a neopentyl group, a 2-hexyl group and a 3-hexyl group, and the like.

In the above formula (2), the cycloalkyl group represented by R¹ and R² is preferably a cycloalkyl group having 3 to 20 carbon atoms. The cycloalkyl group may be polycyclic, and an oxygen atom may be included in the ring. Examples of the cycloalkyl group include a cyclopropyl group, a cyclopentyl group, a cyclohexyl group, a cycloheptyl group, a cyclooctyl group, a bornyl group, a norbornyl group, an adamantyl group, and the like.

In the above formula (2), the aryl group represented by R¹ and R² is preferably an aryl group having 6 to 14 carbon atoms. The aryl group may be monocyclic, may have a structure in which monocycles are linked, or may be a condensed ring. Examples of the aryl group include a phenyl group, a naphthyl group, and the like.

A part or all of hydrogen atoms of the R¹ and R² may be substituted. Examples of the substituent include, a halogen atom, a hydroxyl group, a nitro group, a cyano group, a carboxyl group, a carbonyl group, a cycloalkyl group (for this cycloalkyl group, the above explanation of the cycloalkyl group may be suitably applied), an aryl group (for this aryl group, the above explanation of the aryl group may be suitably applied), an alkoxy group (preferably, an alkoxy group having 1 to 20 carbon atoms, such as, for example, a methoxy group, an ethoxy group, a propoxy group, a n-butoxy group, a pentyloxy group, a hexyloxy group, a heptyloxy group, an octyloxy group, etc.), an acyl group (preferably an acyl group having 2 to 20 carbon atoms, such as, for example, an acetyl group, a propionyl group, a butyryl group, an i-butyryl group, etc.), an acyloxy group (preferably an acyloxy group having 2 to 10 carbon atoms, such as, for example, an acetoxy group, an ethylyloxy group, a butyryloxy group, a t-butyryloxy group, a t-amyryloxy group, etc.), an alkoxycarbonyl group (preferably an alkoxycarbonyl group having 2 to 20 carbon atoms, such as, for example, a methoxycarbonyl group, an ethoxycarbonyl group, a propoxy carbonyl group, etc.), a haloalkyl group (a group derived from the aforementioned alkyl group or cycloalkyl group by substituting a part or all of hydrogen atoms with a halogen atom, such as, for example, a perfluoromethyl group, a perfluoroethyl group, a perfluoropropyl group, a fluorocyclopropyl group, a fluorocyclobutyl group, etc.), and the like. With regard to the ring structure in the aryl group, the cycloalkyl group and the like, the alkyl group described above may be included as an additional substituent.

In the above formula (2), the alkyl group, the cycloalkyl group and the aryl group represented by R³ may be similarly defined to R¹ and R². In the above formula (2), the aralkyl group represented by R³ is preferably an aralkyl group having 7 to 20 carbon atoms, such as, for example, a benzyl group, a phenethyl group, a naphthylmethyl group, a naphthylethyl group, and the like. In the above formula (1), a group represented by -M (R^{3 m})₃ for R³ may be, for example, a trimethylsilanyl group, a trimethylgermyl group, and the like. A part or all of hydrogen atoms of the aralkyl group or the group represented by -M (R^{3 m})₃ for R³ may be substituted with the aforementioned substituent.

R¹ and R³ may link to form a cyclic ether. Examples of such a cyclic ether include, a 2-oxetanyl group, a 2-tetrahydrofuranyl group, a 2-tetrahydropyranyl group, a 2-dioxanyl group, and the like. A part or all of hydrogen atoms of this cyclic ether may be substituted with the aforementioned substituent.

The structure unit (1) can have an acetal structure or a ketal structure thereof by having a functional group that provides an acetal structure or a ketal structure via binding to other carbon atom.

Examples of the functional group that provides an acetal structure or a ketal structure via binding to other carbon atom include a 1-methoxyethoxy group, a 1-ethoxyethoxy group, a 1-n-propoxyethoxy group, a 1-i-propoxyethoxy group, a 1-n-butoxyethoxy group, a 1-i-butoxyethoxy group, a 1-sec-butoxyethoxy group, a 1-t-butoxyethoxy group, a 1-cyclopentyloxyethoxy group, a 1-cyclohexyloxyethoxy group, a 1-norbornyloxyethoxy group, a 1-bornyloxyethoxy group, a 1-phenyloxyethoxy group, a 1-(1-naphthyloxy)ethoxy group, a 1-benzyloxyethoxy group, a 1-phenethyloxyethoxy group, a (cyclohexyl)(methoxy)methoxy group, a (cyclohexyl)(ethoxy)methoxy group, a (cyclohexyl)(n-propoxy)methoxy group, a (cyclohexyl) (i-propoxy)methoxy group, a (cyclohexyl)(cyclohexyloxy)methoxy group, a (cyclohexyl)(phenoxy)methoxy group, a (cyclohexyl)(benzyloxy)methoxy group, a (phenyl)(methoxy)methoxy group, a (phenyl)(ethoxy)methoxy group, a (phenyl)(n-propoxy)methoxy group, a (phenyl)(i-propoxy)methoxy group, a (phenyl)(cyclohexyloxy)methoxy group, a (phenyl)(phenoxy)methoxy group, a (phenyl)(benzyloxy)methoxy group, a (benzyl)(methoxy)methoxy group, a (benzyl)(ethoxy)methoxy group, a (benzyl)(n-propoxy)methoxy group, a (benzyl)(i-propoxy)methoxy group, a (benzyl)(cyclohexyloxy)methoxy group, a (benzyl)(phenoxy)methoxy group, a (benzyl)(benzyloxy)methoxy group, a 2-tetrahydrofuranyloxy group, a 2-tetrahydropyranyloxy group, a 1-trimethylsilanyloxyethoxy group, a 1-trimethylgermyloxyethoxy group, and the like.

Of these, a 1-ethoxyethoxy group, a 1-cyclohexyloxyethoxy group, a 2-tetrahydropyranyloxy group, a 1-n-propoxyethoxy group, a 1-n-butoxyethoxy group, and a 2-tetrahydropyranyloxy group are preferred.

Examples of the functional group that provides a ketal structure via binding to other carbon atom include a 1-methyl-1-methoxyethoxy group, a 1-methyl-1-ethoxyethoxy group, a 1-methyl-1-n-propoxyethoxy group, a 1-methyl-1-i-propoxyethoxy group, a 1-methyl-1-n-butoxyethoxy group, a 1-methyl-1-i-butoxyethoxy group, a 1-methyl-1-sec-butoxyethoxy group, a 1-methyl-1-t-butoxyethoxy group, a 1-methyl-1-cyclopentyloxyethoxy group, a 1-methyl-1-cyclohexyloxyethoxy group, a 1-methyl-1-norbornyloxyethoxy group, a 1-methyl-1-bornyloxyethoxy group, a 1-methyl-1-phenyloxyethoxy group, a 1-methyl-1-(1-naphthyloxy)ethoxy group, a 1-methyl-1-benzyloxyethoxy group, a 1-methyl-1-phenethyloxyethoxy group, a 1-cyclohexyl-1-methoxyethoxy group, a 1-cyclohexyl-1-ethoxyethoxy group, a 1-cyclohexyl-1-n-propoxyethoxy group, a 1-cyclohexyl-1-i-propoxyethoxy group, a 1-cyclohexyl-1-cyclohexyloxyethoxy group, a 1-cyclohexyl-1-phenoxyethoxy group, a 1-cyclohexyl-1-benzyloxyethoxy group, a 1-phenyl-1-methoxyethoxy group, a 1-phenyl-1-ethoxyethoxy group, a 1-phenyl-1-n-propoxyethoxy group, a 1-phenyl-1-i-propoxyethoxy group, a 1-phenyl-1-cyclohexyloxyethoxy group, a 1-phenyl-1-phenyloxyethoxy group, a 1-phenyl-1-benzyloxyethoxy group, a 1-benzyl-1-methoxyethoxy group, a 1-benzyl-1-ethoxyethoxy group, a 1-benzyl-1-n-propoxyethoxy group, a 1-benzyl-1-i-propoxyethoxy group, a 1-benzyl-1-cyclohexyloxyethoxy group, a 1-benzyl-1-phenyloxyethoxy group, a 1-benzyl-1-benzyloxyethoxy group, a 2-(2-methyl-tetrahydrofuranyl)oxy group, a 2-(2-methyl-tetrahydropyranyl) oxy group, a 1-methoxy-cyclopentyloxy group, a 1-methoxy-cyclohexyloxy group, and the like.

Of these, a 1-methyl-1-methoxyethoxy group, and a 1-methyl-1-cyclohexyloxyethoxy group are preferred.

The structure unit (1) having an acetal structure or a ketal structure may include, for example, a structure unit represented by the following formulae (2-1) to (2-3), and the like.

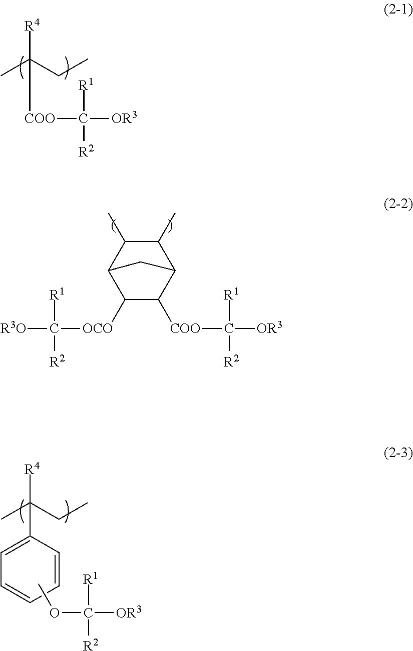

In the above formulae (2-1) and (2-3), R⁴ represents a hydrogen atom or a methyl group. R¹, R² and R³ are as defined in connection with the above formula (2).

Examples of the radical-polymerizable monomer that provides the structure unit (1) represented by the above formulae (2-1) to (2-3) (hereinafter, may also referred to as “acetal structure-containing monomer”) include: (meth)acrylate based acetal structure-containing monomers such as 1-alkoxyalkyl (meth)acrylate, 1-(cycloalkyloxy)alkyl (meth)acrylate, 1-(haloalkoxy)alkyl (meth)acrylate, 1-(aralkyloxy)alkyl (meth)acrylate, and tetrahydropyranyl (meth)acrylate; norbornene based acetal structure-containing monomers such as 2,3-di(1-(trialkylsilanyloxy)alkoxy)carbonyl)-5-norbornene, 2,3-di(1-(trialkylgermyloxy)alkoxy)carbonyl)-5-norbornene, 2,3-di(1-alkoxyalkoxycarbonyl)-5-norbornene, 2,3-di(1-(cycloalkyloxy)alkoxycarbonyl)-5-norbornene, and 2,3-di(1-(aralkyloxy)alkoxycarbonyl)-5-norbornene; styrene based acetal structure-containing monomers such as 1-alkoxyalkoxystyrene, 1-(haloalkoxy)alkoxystyrene, 1-(aralkyloxy)alkoxystyrene, and tetrahydropyranyloxystyrene, and the like.

More specific examples of the acetal structure-containing monomer include 1-ethoxyethyl methacrylate, 1-methoxyethyl methacrylate, 1-n-butoxyethyl methacrylate, 1-isobutoxyethyl methacrylate, 1-t-butoxyethyl methacrylate, 1-(2-chloroethoxy)ethyl methacrylate, 1-(2-ethylhexyloxy)ethyl methacrylate, 1-n-propoxyethyl methacrylate, 1-cyclohexyloxyethyl methacrylate, 1-(2-cyclohexyl ethoxy)ethyl methacrylate, 1-benzyloxyethyl methacrylate, 2-tetrahydropyranyl methacrylate, 1-ethoxyethyl acrylate, 1-methoxyethyl acrylate, 1-n-butoxyethyl acrylate, 1-isobutoxyethyl acrylate, 1-t-butoxyethyl acrylate, 1-(2-chloroethoxy)ethyl acrylate, 1-(2-ethylhexyloxy)ethyl acrylate, 1-n-propoxyethyl acrylate, 1-cyclohexyloxyethyl acrylate, 1-(2-cyclohexyl ethoxy)ethyl acrylate, 1-benzyloxyethyl acrylate, 2-tetrahydropyranyl acrylate, 2,3-di(1-(trimethylsilanyloxy)ethoxy)carbonyl)-5-norbornene, 2,3-di(1-(trimethylgermyloxy)ethoxy)carbonyl)-5-norbornene, 2,3-di(1-methoxyethoxycarbonyl)-5-norbornene, 2,3-di(1-(cyclohexyloxy)ethoxycarbonyl)-5-norbornene, 2,3-di(1-(benzyloxy)ethoxycarbonyl)-5-norbornene, p or m-1-ethoxyethoxystyrene, p or m-1-methoxyethoxystyrene, p or m-1-n-butoxyethoxystyrene, p or m-1-isobutoxyethoxystyrene, p or m-1-(1,1-dimethylethoxy)ethoxystyrene, p or m-1-(2-chloroethoxy)ethoxystyrene, p or m-1-(2-ethylhexyloxy)ethoxystyrene, p or m-1-n-propoxyethoxystyrene, p or m-1-cyclohexyloxyethoxystyrene, p or m-1-(2-cyclohexyl ethoxy)ethoxystyrene, p or m-1-benzyloxyethoxystyrene, and the like. The structure unit (1) may be used alone, or two or more thereof may be used in combination.

Among these acetal structure-containing monomers, 1-alkoxyalkyl (meth)acrylate, tetrahydropyranyl (meth)acrylate, 1-alkoxyalkoxystyrene and tetrahydropyranyloxystyrene are preferred, where 1-alkoxyalkyl (meth)acrylate are more preferred, and 1-ethoxyethyl methacrylate, 1-n-butoxyethyl methacrylate, 2-tetrahydropyranyl methacrylate and 1-benzyloxyethyl methacrylate are particularly preferred.

As the acetal structure-containing monomer that provides the structure unit (1), a commercially available product may be used, and a product synthesized by a well-known method may be also used. For example, the acetal structure-containing monomer represented by the above formula (2-1) can be synthesized by allowing a (meth)acrylic acid represented by the following reaction formula to react with vinyl ether in the presence of an acid catalyst.

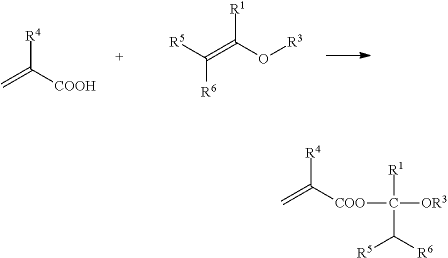

In the above reaction formula, R⁴, R¹ and R³ are each defined similarly to those in the above formulae (2) and (2-1). R⁵ and R⁶ in terms of —CH(R⁵)(R⁶) are similarly defined to R² in the above formula (2).

The content of the structure unit (1) in the polymer (A) is not particularly limited as long as the polymer (A) exhibits alkali-solubility by an acid, and desired heat resistance of the cured film is attained. When the structure unit (1) and the epoxy group-containing structure unit are both included in one polymer molecule, the monomer charge ratio relative to an entirety of the structure units included in the polymer (A) is preferably 5% by mass to 70% by mass, more preferably 10% by mass to 60% by mass or less, and particularly preferably 20% by mass to 50% by mass.

On the other hand, when one polymer molecule has the structure unit (1), and another one polymer molecule has the epoxy group-containing structure unit, the content of the structure unit (1) in the one polymer molecule having the structure unit (1) relative to an entirety of the structure units included in the polymer molecule is preferably 40% by mass to 99% by mass, more preferably 50% by mass to 98% by mass, and particularly preferably 55% by mass to 95% by mass, by the monomer charge ratio.

### (Epoxy Group-Containing Structure Unit)

The polymer (A) has the epoxy group-containing structure unit, in addition to the structure unit (1). The epoxy group-containing structure unit is a structure unit derived from a radical-polymerizable epoxy group-containing monomer. The epoxy group may be exemplified by an oxiranyl group (1,2-epoxy structure), and an oxetanyl group (1,3-epoxy structure). Since the polymer (A) has in the molecule a structure unit including an oxiranyl group, an oxetanyl group or the like, the hardness of the cured film obtained from the positive type radiation sensitive composition is improved, and the heat resistance can be further increased.

Examples of the epoxy group-containing monomer that provides the epoxy group-containing structure unit include: oxiranyl group-containing (meth)acrylic compounds such as glycidyl acrylate, glycidyl methacrylate, 3,4-epoxybutyl acrylate, 3,4-epoxybutyl methacrylate, 3-methyl-3,4-epoxybutyl acrylate, 3-ethyl-3,4-epoxybutyl methacrylate, 5,6-epoxyhexyl acrylate, 5,6-epoxyhexyl methacrylate, 5-methyl-5,6-epoxyhexyl methacrylate, 5-ethyl-5,6-epoxyhexyl methacrylate, 6,7-epoxyheptyl acrylate, 6,7-epoxyheptyl methacrylate, 3,4-epoxycyclohexyl methacrylate, 3,4-epoxycyclohexylmethyl methacrylate, 3,4-epoxycyclohexylethyl methacrylate, 3,4-epoxycyclohexylpropyl methacrylate, 3,4-epoxycyclohexylbutyl methacrylate, 3,4-epoxycyclohexylhexyl methacrylate, 3,4-epoxycyclohexyl acrylate, 3,4-epoxycyclohexylmethyl acrylate, 3,4-epoxycyclohexylethyl acrylate, 3,4-epoxycyclohexylpropyl acrylate, 3,4-epoxycyclohexylbutyl acrylate, and 3,4-epoxycyclohexylhexyl acrylate; vinylbenzylglycidyl ethers such as o-vinylbenzylglycidyl ether, m-vinylbenzylglycidyl ether, p-vinylbenzylglycidyl ether, α-methyl-o-vinylbenzylglycidyl ether, α-methyl-m-vinylbenzylglycidyl ether, and α-methyl-p-vinylbenzylglycidyl ether; vinylphenylglycidyl ethers such as o-vinylphenylglycidyl ether, m-vinylphenylglycidyl ether, and p-vinylphenylglycidyl ether; oxetanyl group-containing (meth)acrylic compounds such as 3-(acryloyloxymethyl)oxetane, 3-(acryloyloxymethyl)-3-methyloxetane, 3-(acryloyloxymethyl)-3-ethyloxetane, 3-(acryloyloxymethyl)-3-phenyloxetane, 3-(2-acryloyloxyethyl)oxetane, 3-(2-acryloyloxyethyl)-3-ethyloxetane, 3-(2-acryloyloxyethyl)-3-ethyloxetane, 3-(2-acryloyloxyethyl)-3-phenyloxetane, 3-(methacryloyloxymethyl)oxetane, 3-(methacryloyloxymethyl)-3-methyloxetane, 3-(methacryloyloxymethyl)-3-ethyloxetane, 3-(methacryloyloxymethyl)-3-phenyloxetane, 3-(2-methacryloyloxyethyl)oxetane, 3-(2-methacryloyloxyethyl)-3-ethyloxetane, 3-(2-methacryloyloxyethyl)-3-ethyloxetane, 3-(2-methacryloyloxyethyl)-3-phenyloxetane, 2-(acryloyloxymethyl)oxetane, 2-(acryloyloxymethyl)-2-methyloxetane, 2-(acryloyloxymethyl)-2-ethyloxetane, 2-(acryloyloxymethyl)-2-phenyloxetane, 2-(2-acryloyloxyethyl)oxetane, 2-(2-acryloyloxyethyl)-2-ethyloxetane, 2-(2-acryloyloxyethyl)-2-ethyloxetane, 2-(2-acryloyloxyethyl)-2-phenyloxetane, 2-(methacryloyloxymethyl)oxetane, 2-(methacryloyloxymethyl)-2-methyloxetane, 2-(methacryloyloxymethyl)-2-ethyloxetane, 2-(methacryloyloxymethyl)-2-phenyloxetane, 2-(2-methacryloyloxyethyl)oxetane, 2-(2-methacryloyloxyethyl)-2-ethyloxetane, 2-(2-methacryloyloxyethyl)-2-ethyloxetane, and 2-(2-methacryloyloxyethyl)-2-phenyloxetane, and the like. The epoxy group-containing structure unit may be used alone, or two or more thereof may be used in combination.

Among the epoxy group-containing monomers, glycidyl methacrylate, 2-methylglycidyl methacrylate, 3,4-epoxycyclohexyl methacrylate, 3,4-epoxycyclohexylmethyl methacrylate, 3-(methacryloyloxymethyl)-3-methyloxetane, and 3-(methacryloyloxymethyl)-3-ethyloxetane are preferred in light of copolymerization reactivity with other radical-polymerizable monomer, and developability of the positive type radiation sensitive composition.

The content of the epoxy group-containing structure unit in the polymer (A) is not particularly limited as long as desired heat resistance of the interlayer insulating film is attained. When the structure unit (1) and the epoxy group-containing structure unit are included in one polymer molecule, the monomer charge ratio relative to an entirety of the structure units included in the polymer (A) is preferably 10% by mass to 60% by mass, more preferably 15% by mass to 55% by mass, and particularly preferably 20% by mass to 50% by mass.

On the other hand, when one polymer molecule has the structure unit (1), and another one polymer molecule has the epoxy group-containing structure unit, the content of the epoxy group-containing structure unit relative to an entirety of the structure units included in the one polymer molecule having the epoxy group-containing structure unit is preferably 20% by mass to 80% by mass, more preferably 30% by mass to 70% by mass, and particularly preferably 35% by mass to 65% by mass, by the monomer charge ratio.

### (Other Structure Unit)

The radical-polymerizable monomer that provides other structure unit may be exemplified by a radical-polymerizable monomer having a carboxyl group or a derivative thereof, or a hydroxyl group, and the like.

Examples of the radical-polymerizable monomer having a carboxyl group or a derivative thereof include: monocarboxylic acids such as acrylic acid, methacrylic acid, crotonic acid, 2-acryloyloxyethylsuccinic acid, 2-methacryloyloxyethylsuccinic acid, 2-acryloyloxyethylhexahydrophthalic acid, and 2-methacryloyloxyethylhexahydrophthalic acid; dicarboxylic acids such as maleic acid, fumaric acid, citraconic acid, mesaconic acid, and itaconic acid; acid anhydrides of the above-described dicarboxylic acid, and the like.

Examples of the radical-polymerizable monomer having a hydroxyl group include: acrylic acid hydroxyalkyl esters such as an acrylic acid-2-hydroxyethyl ester, an acrylic acid-3-hydroxypropyl ester, an acrylic acid-4-hydroxybutyl ester, and an acrylic acid-4-hydroxymethylcyclohexylmethyl ester; methacrylic acid hydroxyalkyl esters such as a methacrylic acid-2-hydroxyethyl ester, a methacrylic acid-3-hydroxypropyl ester, a methacrylic acid-4-hydroxybutyl ester, a methacrylic acid-5-hydroxypentyl ester, a methacrylic acid-6-hydroxyhexyl ester, and a methacrylic acid-4-hydroxymethyl-cyclohexylmethyl ester, and the like.

Among the radical-polymerizable monomers having a hydroxyl group, an acrylic acid-2-hydroxyethyl ester, an acrylic acid-3-hydroxypropyl ester, an acrylic acid-4-hydroxybutyl ester, a methacrylic acid-2-hydroxyethyl ester, a methacrylic acid-4-hydroxybutyl ester, an acrylic acid-4-hydroxymethyl-cyclohexylmethyl ester, and a methacrylic acid-4-hydroxymethyl-cyclohexylmethyl ester are preferred in light of copolymerization reactivity with the other radical-polymerizable monomer, and heat resistance of the resulting interlayer insulating film.

Examples of the other radical-polymerizable monomer include: acrylic acid alkyl esters such as methyl acrylate, and i-propyl acrylate; methacrylic acid alkyl esters such as methyl methacrylate, ethyl methacrylate, n-butyl methacrylate, sec-butyl methacrylate, and t-butyl methacrylate; acrylic acid alicyclic alkyl esters such as cyclohexyl acrylate, 2-methylcyclohexyl acrylate, tricyclo[5.2.1.0^{2,6}]decan-8-yl acrylate, 2-(tricyclo[5.2.1.0^{2,6}]decan-8-yloxy)ethyl acrylate, and isobornyl acrylate; methacrylic acid alicyclic alkyl esters such as cyclohexyl methacrylate, 2-methylcyclohexyl methacrylate, tricyclo[5.2.1.0^{2,6}]decan-8-yl methacrylate, 2-(tricyclo[5.2.1.0^{2,6}]decan-8-yloxy)ethyl methacrylate, and isobornyl methacrylate; aryl esters of acrylic acid such as phenyl acrylate and benzyl acrylate, and aralkyl esters of acrylic acid; aryl esters of methacrylic acid such as phenyl methacrylate and benzyl methacrylate, and aralkyl esters of methacrylic acid; dicarboxylic acid dialkyl esters such as diethyl maleate, diethyl fumarate, and diethyl itaconate; unsaturated five-membered heterocyclic methacrylic acid ester including one oxygen atom such as tetrahydrofurfuryl methacrylate, tetrahydrofuryl methacrylate and tetrahydropyran-2-methyl methacrylate, and unsaturated six-membered heterocyclic methacrylic acid esters; unsaturated five-membered heterocyclic methacrylic acid esters including two oxygen atoms such as 4-methacryloyloxymethyl-2-methyl-2-ethyl-1,3-dioxolane, 4-methacryloyloxymethyl-2-methyl-2-isobutyl-1,3-dioxolane, 4-methacryloyloxymethyl-2-cyclohexyl-1,3-dioxolane, 4-methacryloyloxymethyl-2-methyl-2-ethyl-1,3-dioxolane, and 4-methacryloyloxymethyl-2-methyl-2-isobutyl-1,3-dioxolan; unsaturated five-membered heterocyclic acrylic acid esters including two oxygen atoms such as 4-acryloyloxymethyl-2,2-dimethyl-1,3-dioxolane, 4-acryloyloxymethyl-2-methyl-2-ethyl-1,3-dioxolane, 4-acryloyloxymethyl-2,2-diethyl-1,3-dioxolane, 4-acryloyloxymethyl-2-methyl-2-isobutyl-1,3-dioxolane, 4-acryloyloxymethyl-2-cyclopentyl-1,3-dioxolane, 4-acryloyloxymethyl-2-cyclohexyl-1,3-dioxolane, 4-acryloyloxyethyl-2-methyl-2-ethyl-1,3-dioxolane, 4-acryloyloxypropyl-2-methyl-2-ethyl-1,3-dioxolane, and 4-acryloyloxybutyl-2-methyl-2-ethyl-1,3-dioxolane; aromatic vinyl compounds such as styrene, α-methylstyrene, m-methylstyrene, p-methylstyrene, p-methoxystyrene, and 4-isopropenylphenol; N-substituted maleimides such as N-phenylmaleimide, N-cyclohexylmaleimide, N-benzylmaleimide, N-succinimidyl-3-maleimidebenzoate, N-succinimidyl-4-maleimidebutyrate, N-succinimidyl-6-maleimidecaproate, N-succinimidyl-3-maleimidepropionate, and N-(9-acridinyl)maleimide; conjugated diene based compounds such as 1,3-butadiene, isoprene, and 2,3-dimethyl-1,3-butadiene; other unsaturated compounds such as acrylonitrile, methacrylonitrile, acrylamide, methacrylamide, vinyl chloride, vinylidene chloride, vinyl acetate, and the like.

Among these other radical-polymerizable monomers, styrene, 4-isopropenylphenol, tricyclo[5.2.1.0^{2,6}]decan-8-yl methacrylate, tetrahydrofurfuryl methacrylate, 1,3-butadiene, 4-acryloyloxymethyl-2-methyl-2-ethyl-1,3-dioxolane, N-cyclohexylmaleimide, N-phenylmaleimide, and benzyl methacrylate are preferred in light of copolymerization reactivity with the radical-polymerizable monomer having a reactive functional group, and developability of the positive type radiation sensitive composition.

The weight average molecular weight (Mw) in terms of the polystyrene equivalent of the polymer (A) on GPC (gel permeation chromatography) is preferably 2.0×10³ to 1.0×10⁵, and more preferably 5.0×10³ to 5.0×10⁴. When the Mw of the polymer (A) falls within the above specific range, radioactive ray sensitivity and alkali developability of the positive type radiation sensitive composition can be improved.

The number average molecular weight (Mn) in terms of the polystyrene equivalent of the polymer (A) on GPC is preferably 2.0×10³ to 1.0×10⁵, and more preferably 5.0×10³ to 5.0×10⁴. When the Mn of the copolymer falls within the above specific range, curing reactivity of the coated film of the positive type radiation sensitive composition upon curing can be improved.

The molecular weight distribution (Mw/Mn) of the polymer (A) is preferably no greater than 3.0, and more preferably no greater than 2.6. When the Mw/Mn of the polymer (A) is no greater than 3.0, developability of the resultant interlayer insulating film can be improved. The positive type radiation sensitive composition containing the polymer (A) enables a desired pattern configuration to be easily formed without generating development residues when developed.

### (Method for Producing Polymer (A))

The polymer (A) can be produced by radical copolymerization of, for example, an acetal structure-containing monomer, an epoxy group-containing monomer, or other monomer that provides the structure unit. For producing the polymer (A) having the structure unit (1) and the epoxy group-containing structure unit both in an identical polymer molecule, a mixture containing at least the acetal structure-containing monomer and the epoxy group-containing monomer may be used to allow for copolymerization. On the other hand, for producing the polymer (A) having the structure unit (1) in one polymer molecule, and the epoxy group-containing structure unit in a polymer molecule distinct from the former polymer molecule, a polymerizable solution containing at least the acetal structure-containing monomer is subjected to radical polymerization to obtain polymer molecules having the structure unit (1), whereas a polymerizable solution containing at least the epoxy group-containing monomer is separately submitted to radical polymerize to obtain polymer molecules having the epoxy group-containing structure unit, and finally both are mixed to give the polymer (A).

The solvent used in the polymerization reaction for producing the polymer (A) may include, for example, alcohols, ethers, glycol ethers, ethylene glycol alkyl ether acetate, diethylene glycol alkyl ethers, propylene glycol monoalkyl ethers, propylene glycol monoalkyl ether acetates, propylene glycol monoalkyl ether propionates, aromatic hydrocarbons, ketones, other esters, and the like.

Examples of the alcohols include methanol, ethanol, benzyl alcohol, 2-phenylethyl alcohol, 3-phenyl-1-propanol, and the like.

Examples of the ethers include tetrahydrofuran, and the like.

Examples of the glycol ether include ethylene glycol monomethyl ether, ethylene glycol monoethyl ether, and the like.

Examples of the ethylene glycol alkyl ether acetate include methyl cellosolve acetate, ethyl cellosolve acetate, ethylene glycol monobutyl ether acetate, ethylene glycol monoethyl ether acetate, and the like.

Examples of the diethylene glycol alkyl ether include diethylene glycol monomethyl ether, diethylene glycol monoethyl ether, diethylene glycol dimethyl ether, diethylene glycol diethyl ether, diethylene glycol ethylmethyl ether, and the like.

Examples of the propylene glycol monoalkyl ether include propylene glycol monomethyl ether, propylene glycol monoethyl ether, propylene glycol monopropyl ether, propylene glycol monobutyl ether, and the like.

Examples of the propylene glycol monoalkyl ether acetate include propylene glycol monomethyl ether acetate, propylene glycol monoethyl ether acetate, propylene glycol monopropyl ether acetate, propylene glycol monobutyl ether acetate, and the like.

Examples of the propylene glycol monoalkyl ether propionate include propylene monoglycol methyl ether propionate, propylene glycol monoethyl ether propionate, propylene glycol monopropyl ether propionate, propylene glycol monobutyl ether propionate, and the like.

Examples of the aromatic hydrocarbons include toluene, xylene, and the like.

Examples of the ketones include methyl ethyl ketone, cyclohexanone, 4-hydroxy-4-methyl-2-pentanone, and the like.

Examples of the other esters include methyl acetate, ethyl acetate, propyl acetate, butyl acetate, ethyl 2-hydroxypropionate, methyl 2-hydroxy-2-methylpropionate, ethyl 2-hydroxy-2-methylpropionate, methyl hydroxyacetate, ethyl hydroxyacetate, butyl hydroxyacetate, methyl lactate, ethyl lactate, propyl lactate, butyl lactate, methyl 3-hydroxypropionate, ethyl 3-hydroxypropionate, propyl 3-hydroxypropionate, butyl 3-hydroxypropionate, methyl 2-hydroxy-3-methylbutanoate, methyl methoxyacetate, ethyl methoxyacetate, propyl methoxyacetate, butyl methoxyacetate, methyl ethoxyacetate, ethoxyethyl acetate, propyl ethoxyacetate, butyl ethoxyacetate, methyl propoxyacetate, ethyl propoxyacetate, propyl propoxyacetate, butyl propoxyacetate, methyl butoxyacetate, ethyl butoxyacetate, propyl butoxyacetate, butyl butoxyacetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, butyl 3-butoxypropionate, and the like.

Among these solvents, ethylene glycol alkyl ether acetate, diethylene glycol alkyl ether, propylene glycol monoalkyl ether, propylene glycol monoalkyl ether acetate and butyl methoxyacetate are preferred, and diethylene glycol dimethyl ether, diethylene glycol ethylmethyl ether, propylene glycol monomethyl ether acetate, propylene glycol monomethyl ether and butyl methoxyacetate are more preferred.

As a polymerization initiator for use in the polymerization reaction, a generally known radical polymerization initiator may be used. Examples of the radical polymerization initiator include: azo compounds such as 2,2′-azobisisobutyronitrile, 2,2′-azobis-(2,4-dimethylvaleronitrile), 2,2′-azobis-(4-methoxy-2,4-dimethylvaleronitrile), and 2,2′-azobis(2-methylpropionatemethyl); organic peroxides such as benzoyl peroxide, lauroyl peroxide, t-butylperoxypivalate and 1,1′-bis-(t-butylperoxy)cyclohexane as well as hydrogen peroxide, and the like.

When a peroxide is used as the radical polymerization initiator, the peroxide may be used in combination with a reducing agent to prepare a redox-type initiator.

In the polymerization reaction for producing the polymer (A), a molecular weight modifier may be used for adjusting the molecular weight. Examples of the molecular weight modifier include: halogenated hydrocarbons such as chloroform, and carbon tetrabromide; mercaptans such as n-hexyl mercaptan, n-octyl mercaptan, n-dodecyl mercaptan, t-dodecyl mercaptan, and thioglycolic acid; xanthogens such as dimethyl xanthogen sulfide, and diisopropyl xanthogen disulfide; terpinolene, α-methylstyrene dimer, and the like.

### <(B) Photoacid Generator>

The photoacid generator (B) is a substance that generates an acid upon irradiation with a radioactive ray. Herein, the radioactive ray which may be used is, for example, visible light ray, ultraviolet ray, far ultraviolet ray, electron beam, X-ray, and the like. Since the positive type radiation sensitive composition contains the photoacid generator (B) and the polymer (A) having an acid-dissociable group, positive type radiation-sensitive characteristics can be effected. The photoacid generator (B) is not particularly limited as long as it is a substance that generates an acid (for example, carboxylic acid, sulfonic acid, etc.) upon irradiation with a radioactive ray. Mode of containing the photoacid generator (B) in the positive type radiation sensitive composition may be a form of a photo-acid-generating agent that is a compound as described later (hereinafter, may be also referred to as “(B) photo-acid-generating agent”), a form of a photo-acid-generating group incorporated as a part of the polymer (A) or other polymer, or a form including both of these forms.

The photo-acid-generating agent (B) is exemplified by an oxime sulfonate compound, an onium salt, a sulfonimide compound, a halogen-containing compound, a diazomethane compound, a sulfone compound, a sulfonic acid-esterified product, a carboxylic acid ester compound, and the like. These may be used alone, or in combination of two or more of them.

### (Oxime Sulfonate Compound)

The oxime sulfonate compound is preferably a compound having an oxime sulfonate group represented by the following formula (3).

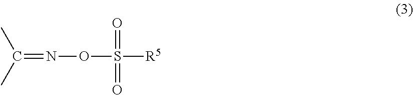

In the above formula (3), R⁵ represents a linear, branched or cyclic alkyl group which may be substituted, or an aryl group which may be substituted. The alkyl group in R⁵ is preferably a linear or branched alkyl group having 1 to 10 carbon atoms. The alkyl group in R⁵ may be substituted with an alkoxy group or an alicyclic group having 1 to 10 carbon atoms (including a bridged alicyclic group such as a 7,7-dimethyl-2-oxonorbornyl group, preferably a bicycloalkyl group). The aryl group in R⁵ is preferably an aryl group having 6 to 11 carbon atoms, and more preferably a phenyl group or a naphthyl group. The aryl group in R⁵ may be substituted with an alkyl group or an alkoxy group having 1 to 5 carbon atoms, or a halogen atom.

The compound having an oxime sulfonate group represented by the above formula (3) is particularly preferably an oxime sulfonate compound represented by the following formula (3-1).

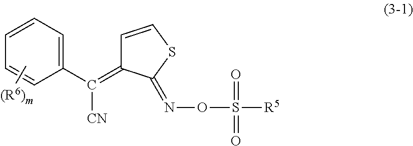

In the above formula (3-1), R⁵ is as defined in the above formula (3). R⁶ is an alkyl group, an alkoxy group or a halogen atom. “m” is an integer of 0 to 3. However, when R⁶ is included in a plural number, a plurality of R⁶s may be the same or different. The alkyl group represented by R⁶ is preferably a linear or branched alkyl group having 1 to 4 carbon atoms.

The alkoxy group represented by R⁶ is preferably a linear or branched alkoxy group having 1 to 4 carbon atoms. The halogen atom represented by X is preferably a chlorine atom or a fluorine atom. “m” is preferably 0 or 1. In a more preferable compound represented by the above formula (3-1): m is 1; R⁶ is a methyl group; and the substitution position of R⁶ is ortho.

The oxime sulfonate compound is exemplified by compounds represented by the following formulae, and the like.

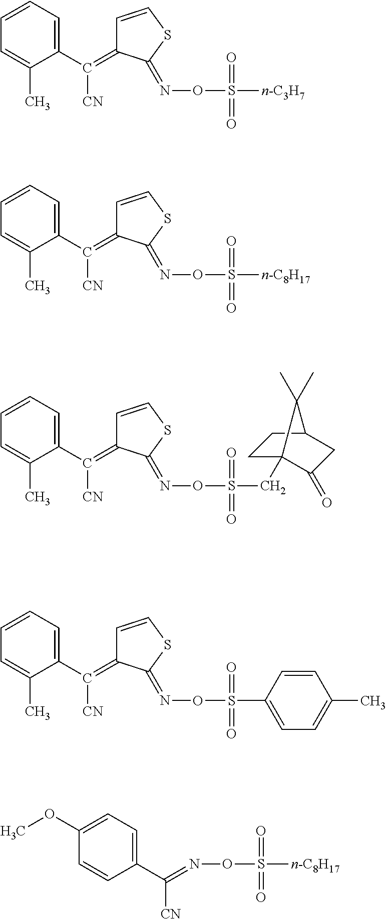

The aforementioned compounds can be obtained as commercially available products in the name of [(5-propylsulfonyloxyimino-5H-thiophen-2-ylidene)-(2-methylphenyl)acetonitrile], [(5-octylsulfonyloxyimino-5H-thiophen-2-ylidene)-(2-methylphenyl)acetonitrile], [(camphorsulfonyloxyimino-5H-thiophen-2-ylidene)-(2-methylphenyl)acetonitrile], [(5-p-toluenesulfonyloxyimino-5H-thiophen-2-ylidene)-(2-methylphenyl)acetonitrile] and [(5-octylsulfonyloxyimino)-(4-methoxyphenyl)acetonitrile], respectively.

### (Onium Salt)

The onium salt is exemplified by a diphenyliodonium salt, a triphenylsulfonium salt, a sulfonium salt, a benzothiazonium salt, a tetrahydrothiophenium salt, and the like.

Examples of the diphenyliodonium salt include diphenyliodonium tetrafluoroborate, diphenyliodonium hexafluorophosphonate, diphenyliodonium hexafluoroarsenate, diphenyliodonium trifluoromethanesulfonate, diphenyliodonium trifluoroacetate, diphenyliodonium p-toluenesulfonate, diphenyliodonium butyltris(2,6-difluorophenyl) borate, 4-methoxyphenylphenyliodonium tetrafluoroborate, bis(4-t-butylphenyl)iodonium tetrafluoroborate, bis(4-t-butylphenyl)iodonium hexafluoroarsenate, bis(4-t-butylphenyl)iodonium trifluoromethanesulfonate, bis(4-t-butylphenyl)iodonium trifluoroacetate, bis(4-t-butylphenyl)iodonium p-toluenesulfonate, bis(4-t-butylphenyl)iodonium camphorsulfonic acid, and the like.

Examples of the triphenylsulfonium salt include triphenylsulfonium trifluoromethanesulfonate, triphenylsulfonium camphorsulfonic acid, triphenylsulfonium tetrafluoroborate, triphenylsulfonium trifluoroacetate, triphenylsulfonium p-toluenesulfonate, triphenylsulfonium butyltris(2,6-difluorophenyl)borate, and the like.

Examples of the sulfonium salt include alkylsulfonium salts, benzylsulfonium salts, dibenzylsulfonium salts, substituted benzylsulfonium salts, and the like.

Examples of the alkylsulfonium salt include 4-acetoxyphenyldimethylsulfonium hexafluoroantimonate, 4-acetoxyphenyldimethylsulfonium hexafluoroarsenate, dimethyl-4-(benzyloxycarbonyloxy)phenylsulfonium hexafluoroantimonate, dimethyl-4-(benzoyloxy)phenylsulfonium hexafluoroantimonate, dimethyl-4-(benzoyloxy)phenylsulfonium hexafluoroarsenate, dimethyl-3-chloro-4-acetoxyphenylsulfonium hexafluoroantimonate, and the like.

Examples of the benzylsulfonium salt include benzyl-4-hydroxyphenylmethylsulfonium hexafluoroantimonate, benzyl-4-hydroxyphenylmethylsulfonium hexafluorophosphate, 4-acetoxyphenylbenzylmethylsulfonium hexafluoroantimonate, benzyl-4-methoxyphenylmethylsulfonium hexafluoroantimonate, benzyl-2-methyl-4-hydroxyphenylmethylsulfonium hexafluoroantimonate, benzyl-3-chloro-4-hydroxyphenylmethylsulfonium hexafluoroarsenate, 4-methoxybenzyl-4-hydroxyphenylmethylsulfonium hexafluorophosphate, and the like.

Examples of the dibenzylsulfonium salt include dibenzyl-4-hydroxyphenylsulfonium hexafluoroantimonate, dibenzyl-4-hydroxyphenylsulfonium hexafluorophosphate, 4-acetoxyphenyldibenzylsulfonium hexafluoroantimonate, dibenzyl-4-methoxyphenylsulfonium hexafluoroantimonate, dibenzyl-3-chloro-4-hydroxyphenylsulfonium hexafluoroarsenate, dibenzyl-3-methyl-4-hydroxy-5-t-butylphenylsulfonium hexafluoroantimonate, benzyl-4-methoxybenzyl-4-hydroxyphenylsulfonium hexafluorophosphate, and the like.

Examples of the substituted benzylsulfonium salt include p-chlorobenzyl-4-hydroxyphenylmethylsulfonium hexafluoroantimonate, p-nitrobenzyl-4-hydroxyphenylmethylsulfonium hexafluoroantimonate, p-chlorobenzyl-4-hydroxyphenylmethylsulfonium hexafluorophosphate, p-nitrobenzyl-3-methyl-4-hydroxyphenylmethylsulfonium hexafluoroantimonate, 3,5-dichlorobenzyl-4-hydroxyphenylmethylsulfonium hexafluoroantimonate, o-chlorobenzyl-3-chloro-4-hydroxyphenylmethylsulfonium hexafluoroantimonate, and the like.

Examples of the benzothiazonium salt include 3-benzylbenzothiazonium hexafluoroantimonate, 3-benzylbenzothiazonium hexafluorophosphate, 3-benzylbenzothiazonium tetrafluoroborate, 3-(p-methoxybenzyl)benzothiazonium hexafluoroantimonate, 3-benzyl-2-methylthiobenzothiazonium hexafluoroantimonate, 3-benzyl-5-chlorobenzothiazonium hexafluoroantimonate, and the like.

Examples of the tetrahydrothiophenium salt include 4,7-di-n-butoxy-1-naphthyltetrahydrothiophenium trifluoromethanesulfonate, 1-(4-n-butoxynaphthalene-1-yl)tetrahydrothiophenium trifluoromethanesulfonate, 1-(4-n-butoxynaphthalene-1-yl)tetrahydrothiophenium nonafluoro-n-butanesulfonate, 1-(4-n-butoxynaphthalene-1-yl)tetrahydrothiophenium 1,1,2,2-tetrafluoro-2-(norbornane-2-yl)ethanesulfonate, 1-(4-n-butoxynaphthalene-1-yl)tetrahydrothiophenium 2-(5-t-butoxycarbonyloxybicyclo[2.2.1]heptane-2-yl)-1,1,2,2-tetrafluoroethanesulfonate, 1-(4-n-butoxynaphthalene-1-yl)tetrahydrothiophenium 2-(6-t-butoxycarbonyloxybicyclo[2.2.1]heptane-2-yl)-1,1,2,2-tetrafluoroethanesulfonate, and the like.

### (Sulfonimide Compound)

Examples of the sulfonimide compound include N-(trifluoromethylsulfonyloxy)succinimide, N-(camphorsulfonyloxy)succinimide, N-(4-methylphenylsulfonyloxy)succinimide, N-(2-trifluoromethylphenylsulfonyloxy)succinimide, N-(4-fluorophenylsulfonyloxy)succinimide, N-(trifluoromethylsulfonyloxy)phthalimide, N-(camphorsulfonyloxy)phthalimide, N-(2-trifluoromethylphenylsulfonyloxy)phthalimide, N-(2-fluorophenylsulfonyloxy)phthalimide, N-(trifluoromethylsulfonyloxy)diphenylmaleimide, N-(camphorsulfonyloxy)diphenylmaleimide, 4-methylphenylsulfonyloxy)diphenylmaleimide, N-(2-trifluoromethylphenylsulfonyloxy)diphenylmaleimide, N-(4-fluorophenylsulfonyloxy)diphenylmaleimide, N-(4-fluorophenylsulfonyloxy)diphenylmaleimide, N-(phenylsulfonyloxy)bicyclo[2.2.1]hept-5-ene-2,3-dicarboxylimide, N-(4-methylphenylsulfonyloxy)bicyclo[2.2.1]hept-5-ene-2,3-dicarboxylimide, N-(trifluoromethanesulfonyloxy)bicyclo[2.2.1]hept-5-ene-2,3-dicarboxylimide, N-(nonafluorobutanesulfonyloxy)bicyclo[2.2.1]hept-5-ene-2,3-dicarboxylimide, N-(camphorsulfonyloxy)bicyclo[2.2.1]hept-5-ene-2,3-dicarboxylimide, N-(camphorsulfonyloxy)-7-oxabicyclo[2.2.1]hept-5-ene-2,3-dicarboxylimide, N-(trifluoromethylsulfonyloxy)-7-oxabicyclo[2.2.1]hept-5-ene-2,3-dicarboxylimide, N-(4-methylphenylsulfonyloxy)bicyclo[2.2.1]hept-5-ene-2,3-dicarboxylimide, N-(4-methylphenylsulfonyloxy)-7-oxabicyclo[2.2.1]hept-5-ene-2,3-dicarboxylimide, N-(2-trifluoromethylphenylsulfonyloxy)bicyclo[2.2.1]hept-5-ene-2,3-dicarboxylimide, N-(2-trifluoromethylphenylsulfonyloxy)-7-oxabicyclo[2.2.1]hept-5-ene-2,3-dicarboxylimide, N-(4-fluorophenylsulfonyloxy)bicyclo[2.2.1]hept-5-ene-2,3-dicarboxylimide, N-(4-fluorophenylsulfonyloxy)-7-oxabicyclo[2.2.1]hept-5-ene-2,3-dicarboxylimide, N-(trifluoromethylsulfonyloxy)bicyclo[2.2.1]heptane-5,6-oxy-2,3-dicarboxylimide, N-(camphorsulfonyloxy)bicyclo[2.2.1]heptane-5,6-oxy-2,3-dicarboxylimide, N-(4-methylphenylsulfonyloxy)bicyclo[2.2.1]heptane-5,6-oxy-2,3-dicarboxylimide, N-(2-trifluoromethylphenylsulfonyloxy)bicyclo[2.2.1]heptane-5,6-oxy-2,3-dicarboxylimide, N-(4-fluorophenylsulfonyloxy)bicyclo[2.2.1]heptane-5,6-oxy-2,3-dicarboxylimide, N-(trifluoromethylsulfonyloxy)naphthyldicarboxylimide, N-(camphorsulfonyloxy)naphthyldicarboxylimide, N-(4-methylphenylsulfonyloxy)naphthyldicarboxylimide, N-(phenylsulfonyloxy)naphthyldicarboxylimide, N-(2-trifluoromethylphenylsulfonyloxy)naphthyldicarboxylimide, N-(4-fluorophenylsulfonyloxy)naphthyldicarboxylimide, N-(pentafluoroethylsulfonyloxy)naphthyldicarboxylimide, N-(heptafluoropropylsulfonyloxy)naphthyldicarboxylimide, N-(nonafluorobutylsulfonyloxy)naphthyldicarboxylimide, N-(ethylsulfonyloxy)naphthyldicarboxylimide, N-(propylsulfonyloxy)naphthyldicarboxylimide, N-(butylsulfonyloxy)naphthyldicarboxylimide, N-(pentylsulfonyloxy)naphthyldicarboxylimide, N-(hexylsulfonyloxy)naphthyldicarboxylimide, N-(heptylsulfonyloxy)naphthyldicarboxylimide, N-(octylsulfonyloxy)naphthyldicarboxylimide, N-(nonylsulfonyloxy)naphthyldicarboxylimide, and the like.

### (Halogen-containing Compound)

Examples of the halogen-containing compound include haloalkyl group-containing hydrocarbon compounds, haloalkyl group-containing heterocyclic compounds, and the like.

### (Diazomethane Compound)

Examples of the diazomethane compound include bis(trifluoromethylsulfonyl)diazomethane, bis(cyclohexylsulfonyl)diazomethane, bis(phenylsulfonyl)diazomethane, bis(p-tolylsulfonyl)diazomethane, bis(2,4-xylylsulfonyl)diazomethane, bis(p-chlorophenylsulfonyl)diazomethane, methylsulfonyl-p-toluenesulfonyldiazomethane, cyclohexylsulfonyl(1,1-dimethylethylsulfonyl)diazomethane, bis(1,1-dimethylethylsulfonyl)diazomethane, phenylsulfonyl(benzoyl)diazomethane, and the like.

### (Sulfone Compound)

Examples of the sulfone compound include β-ketosulfone compounds, β-sulfonylsulfone compounds, diaryldisulfone compounds, and the like.

### (Sulfonic Acid Esterified Product)

Examples of the sulfonic acid esterified product include alkylsulfonic acid esters, haloalkyl sulfonic acid esters, arylsulfonic acid esters, imino sulfonate, and the like.

### (Carboxylic Acid Ester Compound)

Examples of the carboxylic acid ester compound include carboxylic acid o-nitrobenzyl esters, and the like.

Among these photo-acid-generating agents (B), in light of the radioactive ray sensitivity, and solubility in the organic solvent (C), oxime sulfonate compounds are preferred, which are more preferably compounds having an oxime sulfonate group represented by the above formula (3), particularly preferably the oxime sulfonate compounds represented by the above formula (3-1), and most preferably [(5-propylsulfonyloxyimino-5H-thiophen-2-ylidene)-(2-methylphenyl)acetonitrile], [(5-octylsulfonyloxyimino-5H-thiophen-2-ylidene)-(2-methylphenyl)acetonitrile], [(5-p-toluenesulfonyloxyimino-5H-thiophen-2-ylidene)-(2-methylphenyl)acetonitrile], [(camphorsulfonyloxyimino-5H-thiophen-2-ylidene)-(2-methylphenyl)acetonitrile], [(5-octylsulfonyloxyimino)-(4-methoxyphenyl)acetonitrile] which can be obtained as commercially available products.

Alternatively, the photo-acid-generating agent (B) is also preferably an onium salt, more preferably a tetrahydrothiophenium salt and a benzylsulfonium salt, and particularly preferably 4,7-di-n-butoxy-1-naphthyltetrahydrothiophenium trifluoromethanesulfonate and benzyl-4-hydroxyphenylmethylsulfonium hexafluorophosphate.

The content of the photo-acid-generating agent (B) in the positive type radiation sensitive composition is preferably 0.1 parts by mass to 10 parts by mass, and more preferably 1 part by mass to 5 parts by mass relative to 100 parts by mass of the polymer (A). When the content of the photo-acid-generating agent (B) falls within the above specific range, the radioactive ray sensitivity of the positive type radiation sensitive composition can be optimized, and an interlayer insulating film having a high surface hardness can be formed while maintaining the transparency.

### [(C) Organic Solvent]

The positive type radiation sensitive composition is prepared into a dissolved or dispersed state by mixing the polymer (A) and the photoacid generator (B) with the organic solvent (C), and as needed the surfactant (D), as well as other arbitrary component. The organic solvent (C) which may be suitably used uniformly dissolves or disperses the aforementioned each constitutive element, but does not react with each constitutive element.

Examples of the organic solvent (C) include alcohols, ethylene glycol monoalkyl ethers, ethylene glycol dialkyl ethers, propylene glycol monoalkyl ethers, diethylene glycol monoalkyl ethers, diethylene glycol dialkyl ethers, diethylene glycol monoalkyl ether acetates, dipropylene glycol monoalkyl ethers, dipropylene glycol dialkyl ethers, dipropylene glycol monoalkyl ether acetates, lactic acid esters, aliphatic carboxylic acid esters, amides, ketones, and the like. These may be used alone, or two or more thereof may be used in combination.

The organic solvent (C) preferably contains (C1) an organic solvent having a vapor pressure at 20° C. of 0.1 mmHg or greater and less than 1 mmHg (hereinafter, may also referred to as “(C1) organic solvent”), and further (C2) an organic solvent having a vapor pressure at 20° C. of 1 mmHg or greater and 20 mmHg or less (hereinafter, may also referred to as “(C2) organic solvent”). By using the organic solvent (C) having a specific vapor pressure, high-speed coating is enabled while preventing unevenness of coating even if, for example, a coating method with a discharge nozzle is employed. It is to be noted that the measurement of the vapor pressure can be carried out using a well-known method; however, the value of the vapor pressure as referred to herein is a measurement determined by a transpiration method.

Examples of the organic solvent (C1) include: alcohols such as benzyl alcohol; ethylene glycol monoalkyl ethers such as ethylene glycol monomethyl ether, ethylene glycol monoethyl ether, ethylene glycol monopropyl ether, and ethylene glycol monobutyl ether; ethylene glycol dialkyl ethers such as ethylene glycol dimethyl ether, ethylene glycol diethyl ether, and ethylene glycol dipropyl ether; propylene glycol monoalkyl ethers such as propylene glycol monomethyl ether, propylene glycol monoethyl ether, propylene glycol monopropyl ether, and propylene glycol monobutyl ether; diethylene glycol monoalkyl ethers such as diethylene glycol monomethyl ether, and diethylene glycol monoethyl ether; diethylene glycol dialkyl ethers such as diethylene glycol diethyl ether, and diethylene glycol ethylmethyl ether; diethylene glycol monoalkyl ether acetates such as diethylene glycol monomethyl ether acetate, diethylene glycol monoethyl ether acetate, diethylene glycol monopropyl ether acetate, and diethylene glycol monobutyl ether acetate; dipropylene glycol monoalkyl ethers such as dipropylene glycol monomethyl ether, dipropylene glycol monoethyl ether, dipropylene glycol monopropyl ether, and dipropylene glycol monobutyl ether; dipropylene glycol dialkyl ethers such as dipropylene glycol dimethyl ether, and dipropylene glycol diethyl ether; dipropylene glycol monoalkyl ether acetates such as dipropylene glycol monomethyl ether acetate, dipropylene glycol monoethyl ether acetate, dipropylene glycol monopropyl ether acetate, and dipropylene glycol monobutyl ether acetate; lactic acid esters such as n-propyl lactate, isopropyl lactate, n-butyl lactate, isobutyl lactate, n-amyl lactate, and isoamyl lactate; aliphatic carboxylic acid esters such as hydroxyethyl acetate, ethyl 2-hydroxy-2-methylpropionate, ethyl 2-hydroxy-3-methyl butyrate, ethoxyethyl acetate, ethyl 3-methoxypropionate, methyl 3-ethoxypropionate, ethyl 3-ethoxypropionate, 3-methoxybutylacetate, 3-methyl-3-methoxybutylacetate, 3-methyl-3-methoxybutylpropionate, 3-methyl-3-methoxybutylbutyrate, methyl acetoacetate, ethyl acetoacetate, methyl pyruvate, and ethyl pyruvate; amides such as N-methylformamide, N,N-dimethylformamide, N-methylacetamide, and N,N-dimethylacetamide; ketones such as N-methylpyrrolidone, and γ-butyrolactone, and the like. These may be used alone, or two or more thereof may be used in combination.

Examples of the organic solvent (C2) include diethylene glycol dimethyl ether, ethylene glycol monomethyl ether acetate, ethylene glycol monoethyl ether acetate, ethylene glycol monopropyl ether acetate, ethylene glycol monobutyl ether acetate, propylene glycol monomethyl ether acetate, cyclohexanone, ethyl acetate, propyl acetate, n-butyl acetate, methylpropylketone, methylisobutyl ketone, methyl 3-methoxypropionate, methyl lactate, ethyl lactate, and the like. These may be used alone, or two or more thereof may be used in combination.

When the organic solvent (C1) and the organic solvent (C2) are used after mixing, the combination thereof is preferably diethylene glycol ethylmethyl ether/diethylene glycol dimethyl ether, diethylene glycol ethylmethyl ether/propylene glycol monomethyl ether acetate, diethylene glycol ethylmethyl ether/cyclohexanone, diethylene glycol diethyl ether/diethylene glycol dimethyl ether, diethylene glycol diethyl ether/propylene glycol monomethyl ether acetate, diethylene glycol diethyl ether/cyclohexanone, diethylene glycol diethyl ether/methyl 3-methoxypropionate, diethylene glycol diethyl ether/methylisobutyl ketone, and diethylene glycol diethyl ether/n-butyl acetate. It is to be noted that the organic solvent (C1) or the organic solvent (C2) may be used as a mixture of two or more thereof, and the combination is exemplified by diethylene glycol diethyl ether/propylene glycol monomethyl ether acetate/cyclohexanone/methyl 3-methoxypropionate, and the like.

The content of the organic solvent (C2) is preferably 10% by mass or greater and 50% by mass or less relative to the total amount of the organic solvent (C1) and the organic solvent (C2). When the mass ratio of the organic solvent (C1) having a low vapor pressure and the organic solvent (C2) having a high vapor pressure falls within the above specific range, the amount of the residual solvent in the coated film particularly after prebaking is optimized, and the flow performance of the coated film is balanced. As a result, occurrence of unevenness of coating (unevenness due to streaks, pin marks, fuzz, etc.) can be inhibited, whereby uniformity of film thickness can be further improved. In addition, by optimizing the amount of the residual solvent, the amount of acid generation, and the acid-dissociable group can be highly balanced, whereby the radioactive ray sensitivity tends to be favorable.

The solid content of the positive type radiation sensitive composition is 10% by mass or greater and 30% by mass or less, and more preferably 20% by mass or greater and 25% by mass or less. When the solid content of the positive type radiation sensitive composition falls within the above specific range, occurrence of the unevenness of coating can be effectively inhibited.

The viscosity of the positive type radiation sensitive composition at 25° C. is referred to as being preferably 2.0 mPa·s or greater and 10 mPa·s or less. When the viscosity of the positive type radiation sensitive composition falls within the above specific range, well balanced viscosity can be attained to an extent that enables flattening in a spontaneous way even if unevenness of coating occurs, while maintaining the uniformity of the film thickness, and high speed coating properties can be achieved.

### [(D) Surfactant]

The positive type radiation sensitive composition may additionally contain the surfactant (D) for further improving film formability of the positive type radiation sensitive composition. Such a surfactant is exemplified by a fluorochemical surfactant, a silicone based surfactant, and other surfactant. When the positive type radiation sensitive composition contains the surfactant (D), surface smoothness of the coated film can be improved, and as a result, uniformity of film thickness of the formed interlayer insulating film can be improved. Among these surfactants, silicone based surfactants which serve in providing particularly excellent uniformity of the film pressure are preferred.

The fluorochemical surfactant is preferably a compound having a fluoroalkyl group and/or a fluoroalkylene group at a site of at least any of the end, the main chain and the side chain. Examples of the fluorochemical surfactant include 1,1,2,2-tetrafluoro-n-octyl(1,1,2,2-tetrafluoro-n-propyl)ether, 1,1,2,2-tetrafluoro-n-octyl(n-hexyl)ether, hexaethylene glycol di(1,1,2,2,3,3-hexafluoro-n-pentyl)ether, octaethylene glycol di(1,1,2,2-tetrafluoro-n-butyl)ether, hexapropylene glycol di(1,1,2,2,3,3-hexafluoro-n-pentyl)ether, octapropylene glycol di(1,1,2,2-tetrafluoro-n-butyl)ether, sodium perfluoro-n-dodecanesulfonate, 1,1,2,2,3,3-hexafluoro-n-decane, 1,1,2,2,3,3,9,9,10,10-decafluoro-n-dodecane, sodium fluoroalkylbenzenesulfonate, sodium fluoroalkylphosphate, sodium fluoroalkylcarboxylate, diglycerintetrakis(fluoroalkylpolyoxyethylene ether), fluoroalkylammonium iodide, fluoroalkylbetaine, fluoroalkylpolyoxyethylene ether, perfluoroalkylpolyoxyethanol, perfluoroalkylalkoxylate, carboxylic acid fluoroalkyl ester, and the like.

Commercially available products of the fluorochemical surfactant include BM-1000 and BM-1100 (both manufactured by BM CHEMIE), Megafac F142D, Megafac F172, Megafac F173, Megafac F183, Megafac F178, Megafac F191, Megafac F471 and Megafac F476 (manufactured by Dainippon Ink And Chemicals, Incorporated), Fluorad FC-170C, Fluorad FC-171, Fluorad FC-430 and Fluorad FC-431 (manufactured by Sumitomo 3M Limited), Surflon S-112, Surflon S-113, Surflon S-131, Surflon S-141, Surflon S-145, Surflon S-382, Surflon SC-101, Surflon SC-102, Surflon SC-103, Surflon SC-104, Surflon SC-105 and Surflon SC-106 (manufactured by Asahi Glass Co., Ltd.), Eftop EF301, Eftop EF303 and Eftop EF352 (manufactured by Shin Akita Kasei K.K.), and FTERGENT FT-100, FTERGENT FT-110, FTERGENT FT-140A, FTERGENT FT-150, FTERGENT FT-250, FTERGENT FT-251, FTERGENT FT-300, FTERGENT FT-310, FTERGENT FT-400S, FTERGENT FTX-218 and FTERGENT FT-251 (manufactured by Neos Co., Ltd.), and the like.

Examples of the silicone based surfactant include Toray Silicone DC3PA, Toray Silicone DC7PA, Toray Silicone SH11PA, Toray Silicone SH21PA, Toray Silicone SH28PA, Toray Silicone SH29PA, Toray Silicone SH30PA, Toray Silicone SH-190, Toray Silicone SH-193, Toray Silicone SZ-6032, Toray Silicone SF-8428, Toray Silicone DC-57, Toray Silicone DC-190 and SH 8400 FLUID (manufactured by Dow Corning Toray Silicone Co., Ltd.), TSF-4440, TSF-4300, TSF-4445, TSF-4446, TSF-4460 and TSF-4452 (manufactured by GE Toshiba Silicones Co Ltd.), organosiloxane polymer KP341 (manufactured by Shin-Etsu Chemical Co., Ltd.), and the like.

The surfactant (D) may be used alone, or two or more thereof may be used in combination. The content of the surfactant (D) in the positive type radiation sensitive composition is preferably 0.01 parts by mass or greater and 2 parts by mass or less, and more preferably 0.05 parts by mass or greater and 1 part by mass or less relative to 100 parts by mass of the polymer (A). When the content of the surfactant (D) falls within the above specific range, surface smoothness of the coated film can be further improved.

### [Other Arbitrary Component]

The positive type radiation sensitive composition may contain other arbitrary component such as an adhesion aid, a basic compound, and a quinonediazide compound as needed in the range, not to deteriorate desired effects. The other arbitrary component may be used alone, or two or more thereof may be used in combination.

### (Adhesion Aid)

In the positive type radiation sensitive composition, an adhesion aid may be included for improving adhesiveness between the insulating film and a silicone compound such as, for example, silicone, oxidized silicone or silicone nitride, or a metal such as gold, copper or aluminum.

As the adhesion aid, a functional silane coupling agent is preferably used. The functional silane coupling agent is exemplified by a silane coupling agent having a reactive substituent such as, for example, a carboxyl group, a methacryloyl group, an isocyanate group, an epoxy group (preferably an oxiranyl group) or a thiol group, and the like.

Examples of the functional silane coupling agent include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, γ-glycidoxypropylalkyldialkoxysilane, γ-chloropropyltrialkoxysilane, γ-mercaptopropyltrialkoxysilane, β-(3,4-epoxycyclohexyl)ethyltrimethoxysilane, and the like.

Among these functional silane coupling agents, γ-glycidoxypropylalkyldialkoxysilane, β-(3,4-epoxycyclohexyl)ethyltrimethoxysilane, and γ-methacryloxypropyltrimethoxysilane are preferred.

The content of the adhesion aid is preferably 0.5 parts by mass or greater and 20 parts by mass or less, and more preferably 1 part by mass or greater and 10 parts by mass or less relative to 100 parts by mass of the polymer (A). When the amount of the adhesion aid included falls within the above specific range, adhesiveness between the interlayer insulating film adhesiveness with the substrate is improved.

### (Basic Compound)

By containing the basic compound in the positive type radiation sensitive composition, the length of diffusion of the acid generated from the photoacid generator (B) upon exposure can be appropriately controlled, thereby capable of making the pattern developability favorable. The basic compound is exemplified by aliphatic amine, aromatic amine, heterocyclic amine, quaternary ammonium hydroxide, carboxylic acid quaternary ammonium salt, and the like.

Examples of the aliphatic amine include trimethylamine, diethylamine, triethylamine, di-n-propylamine, tri-n-propylamine, di-n-pentylamine, tri-n-pentylamine, diethanolamine, triethanolamine, dicyclohexylamine, dicyclohexylmethylamine, and the like.

Examples of the aromatic amine include aniline, benzylamine, N,N-dimethylaniline, diphenylamine, and the like.

Examples of the heterocyclic amine include pyridine, 2-methylpyridine, 4-methylpyridine, 2-ethylpyridine, 4-ethylpyridine, 2-phenylpyridine, 4-phenylpyridine, N-methyl-4-phenylpyridine, 4-dimethylaminopyridine, imidazole, benzimidazole, 4-methylimidazole, 2-phenylbenzimidazole, 2,4,5-triphenylimidazole, nicotine, nicotinic acid, nicotinic acid amide, quinoline, 8-oxyquinoline, pyrazine, pyrazole, pyridazine, purine, pyrrolidine, piperidine, piperazine, morpholine, 4-methylmorpholine, 1,5-diazabicyclo[4.3.0]-5-nonene, 1,8-diazabicyclo[5.3.0]-7 undecene, and the like.

Examples of the quaternary ammonium hydroxide include tetramethylammonium hydroxide, tetraethylammonium hydroxide, tetra-n-butylammonium hydroxide, tetra-n-hexylammonium hydroxide, and the like.

Examples of the carboxylic acid quaternary ammonium salt include tetramethylammonium acetate, tetramethylammonium benzoate, tetra-n-butylammonium acetate, tetra-n-butylammonium benzoate, and the like.

The content of the basic compound in the positive type radiation sensitive composition is preferably 0.001 parts by mass to 1 part by mass, and more preferably 0.005 parts by mass to 0.2 parts by mass relative to 100 parts by mass of the polymer (A). When the content of the basic compound falls within the above specific range, pattern developability can be made favorable.

### (Quinone Diazide Compound)

The quinonediazide compound is a compound that generates a carboxylic acid upon irradiation with a radioactive ray. As the quinonediazide compound, a condensate of a phenolic compound or an alcoholic compound (hereinafter, may also referred to as “parent nucleus”) with 1,2-naphthoquinonediazidesulfonic acid halide may be used.

The parent nucleus is exemplified by trihydroxybenzophenone, tetrahydroxybenzophenone, pentahydroxybenzophenone, hexahydroxybenzophenone, (polyhydroxyphenyl)alkane, other parent nuclei, and the like.

Examples of the trihydroxybenzophenone include 2,3,4-trihydroxybenzophenone, 2,4,6-trihydroxybenzophenone, and the like.

Examples of the tetrahydroxybenzophenone include 2,2′,4,4′-tetrahydroxybenzophenone, 2,3,4,3′-tetrahydroxybenzophenone, 2,3,4,4′-tetrahydroxybenzophenone, 2,3,4,2′-tetrahydroxy-4′-methylbenzophenone, 2,3,4,4′-tetrahydroxy-3′-methoxybenzophenone, and the like.

Examples of the pentahydroxybenzophenone include 2,3,4,2′,6′-pentahydroxybenzophenone, and the like.

Examples of the hexahydroxybenzophenone include 2,4,6,3′,4′,5′-hexahydroxybenzophenone, 3,4,5,3′,4′,5′-hexahydroxybenzophenone, and the like.

Examples of the (polyhydroxyphenyl)alkane include bis(2,4-dihydroxyphenyl)methane, bis(p-hydroxyphenyl)methane, tris(p-hydroxyphenyl)methane, 1,1,1-tris(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-{1-[4-[1-[4-hydroxyphenyl]-1-methylethyl]phenyl}ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavan, and the like.

Examples of the other parent nuclei include 2-methyl-2-(2,4-dihydroxyphenyl)-4-(4-hydroxyphenyl)-7-hydroxychromane, 1-[1-(3-{1-(4-hydroxyphenyl)-1-methylethyl}-4,6-dihydroxyphenyl)-1-methylethyl]-3-(1-(3-{1-(4-hydroxyphenyl)-1-methylethyl}-4,6-dihydroxyphenyl)-1-methylethyl)benzene, 4,6-bis{1-(4-hydroxyphenyl)-1-methylethyl}-1,3-dihydroxybenzene, and the like.

Among these parent nuclei, 2,3,4,4′-tetrahydroxybenzophenone, 1,1,1-tris(p-hydroxyphenyl)ethane, and 4,4′-[1-[4-[1-[4-hydroxyphenyl]-1-methylethyl]phenyl]ethylidene]bisphenol are preferred.

As the 1,2-naphthoquinonediazidesulfonic acid halide, 1,2-naphthoquinonediazidesulfonic acid chloride is preferred. 1,2-naphthoquinonediazidesulfonic acid chloride include 1,2-naphthoquinonediazide-4-sulfonic acid chloride, 1,2-naphthoquinonediazide-5-sulfonic acid chloride, and the like. Of these, 1,2-naphthoquinonediazide-5-sulfonic acid chloride is preferred.

As the condensate of the phenolic compound or the alcoholic compound with 1,2-naphthoquinonediazidesulfonic acid halide, a condensate of 1,1,1-tris(p-hydroxyphenyl)ethane with 1,2-naphthoquinonediazide-5-sulfonic acid chloride, and a condensate of 4,4′-[1-[4-[1-[4-hydroxyphenyl]-1-methylethyl]phenyl]ethylidene]bisphenol with 1,2-naphthoquinonediazide-5-sulfonic acid chloride are preferred.

In the condensation reaction of the phenolic compound or the alcoholic compound with 1,2-naphthoquinonediazidesulfonic acid halide, 1,2-naphthoquinonediazidesulfonic acid halide may be used in an amount corresponding to preferably 30% by mole to 85% by mole, and more preferably 50% by mole to 70% by mole with respect to the number of OH groups in the phenolic compound or the alcoholic compound. The condensation reaction may be carried out by a well-known method.

In addition, as the quinonediazide compound, 1,2-naphthoquinonediazidesulfonic acid amides such as, for example, 2,3,4-triaminobenzophenone-1,2-naphthoquinonediazide-4-sulfonic acid amide, etc., may be also used suitably that has the parent nucleus illustrated above in which the ester bond was changed to an amide bond.

### (Method for Producing the Positive Type Radiation Sensitive Composition)

The positive type radiation sensitive composition is prepared into a dissolved or dispersed state by mixing the polymer (A) and the photoacid generator (B) with the organic solvent (C), and as an optional component the surfactant (D), as well as other arbitrary component as needed. For example, the positive type radiation sensitive composition can be prepared by mixing (A), (B) and (D) components, and other arbitrary component at a certain ratio in the organic solvent (C).

### <Liquid Crystal Layer>

The liquid crystal layer provided in the liquid crystal display element is formed from a polymerizable liquid crystal composition. The polymerizable liquid crystal composition preferably has photopolymerizability or thermal polymerizability. Due to having the photopolymerizability or thermal polymerizability, the polymerizable liquid crystal composition can form a liquid crystal layer from a polymerizable liquid crystal composition by irradiation of light or heat, and thus efficient production is enabled. Also, since deformation and the like of the interlayer insulating film can be suppressed even if produced via such irradiation of light or heat according to the liquid crystal display element, a high voltage holding ratio and superior productivity can be achieved. The polymerizable liquid crystal composition is exemplified by a thermally cured type polymerizable liquid crystal composition, and a photocured type polymerizable liquid crystal composition.

### [Thermally Cured Type Polymerizable Liquid Crystal Composition]

The thermally cured type polymerizable liquid crystal composition is exemplified by a composition containing a liquid crystal compound and thermopolymerizable compound.

### (Liquid Crystal Compound)

The liquid crystal compound is exemplified by a nematic liquid crystal, a smectic liquid crystal, a cholesteric liquid crystal, and the like. The nematic liquid crystal is preferred as the liquid crystal compound. Also, the liquid crystal may contain a cholesteric liquid crystal, a chiral nematic liquid crystal, a chiral smectic liquid crystal and the like as well as a chiral compound for the purpose of improving the performance.

Specific examples of the liquid crystal compound include 4-substituted benzoic acid 4′-substituted phenyl ester, 4-substituted cyclohexanecarboxylic acid 4′-substituted phenyl ester, 4-substituted cyclohexanecarboxylic acid 4′-substituted biphenyl ester, 4-(4-substituted cyclohexanecarbonyloxy)benzoic acid 4′-substituted phenyl ester, 4-(4-substituted cyclohexyl)benzoic acid 4′-substituted phenyl ester, 4-(4-substituted cyclohexyl)benzoic acid 4′-substituted cyclohexyl ester, 4-substituted 4′-substituted biphenyl, 4-substituted phenyl 4′-substituted cyclohexane, 4-substituted 4″-substituted terphenyl, 4-substituted biphenyl 4′-substituted cyclohexane, 2-(4-substituted phenyl)-5-substituted pyrimidine, compounds represented by the following formulae (a) to (d), and the like.

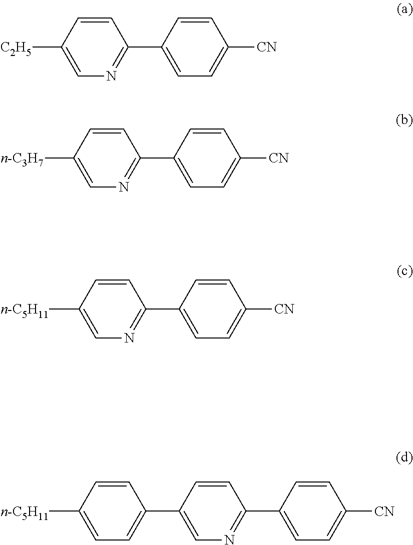

Among these liquid crystal compounds, compounds having a cyano group on at least one end of the molecule, such as the compounds represented by the above formulae (a) to (d) are preferred. These may be used alone, or two or more thereof may be used in combination. These liquid crystal compounds may be used by appropriately selecting and blending them taking into consideration the characteristics of the liquid crystal, i.e., phase transition temperature of the isotropic liquid and liquid crystals, the melting point, the viscosity, anisotropy of the refractive indices (Δn), anisotropy of the relative permittivity (Δε), and miscibility with other component, and the like.

Also, the liquid crystal compound preferably has a polymerizable group. When the liquid crystal compound has a polymerizable group, thermopolymerizability or photopolymerizability can be imparted to the liquid crystal compound per se. The polymerizable group is exemplified by a vinyl group, a (meth)acryl group, a (meth)acryloyl group, a (meth)acrylamide group, a styryl group, an epoxy group, an isocyanate group, and the like.

Examples of liquid crystal compound having a polymerizable group include compounds represented by the following formula (4), and the like.

CH₂═CR—COO—R⁸—R⁹—R¹⁰R¹¹—R¹²ₙR¹³ (4)

In the above formula (4), R⁷ represents a hydrogen atom or a methyl group. R⁸, R¹⁰ and R¹² each independently are any one of groups represented by the following formulae. “n” is 0 or 1. R⁹ and R¹¹ each independently represent a single bond, —CH₂CH₂—, —CH₂O—, —OCH₂—, —COO—, —COO—, —C≡C—, —CH═CH—, —CF═CF—, —(CH₂)₄—, —CH₂CH₂CH₂O—, —OCH₂CH₂CH₂—, —CH₂═CHCH₂CH₂—, or —CH₂CH₂CH═CH—. R¹² represents a hydrogen atom, a halogen atom, a cyano group, an alkyl group, an alkoxy group, an alkenyl group or an alkenyloxy group having 1 to 20 carbon atoms.

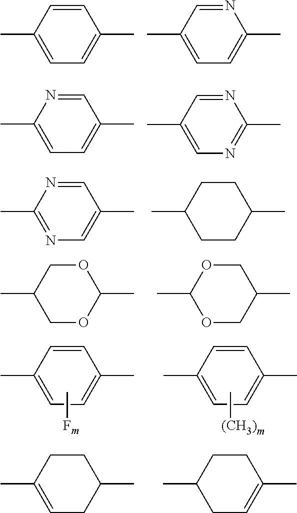

In the above formulae, m is an integer of 1 to 4.

Among the compounds represented by the above formula (4), compounds in which: R⁸, R¹⁰ and R¹² each independently are a group represented by the following formulae; m is 1 or 2; R⁹ and R¹¹ each independently are a single bond or —C≡C—; and R¹³ is a halogen atom, a cyano group, an alkyl group or an alkoxy group having 1 to 20 carbon atoms are preferred.

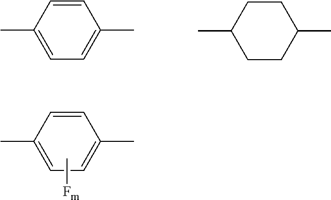

Other liquid crystal compound having a polymerizable group is exemplified by a compound represented by the following formula (5), and the like.

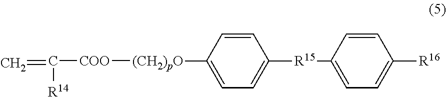

In the above formula (5), R¹⁴ represents a hydrogen atom or a methyl group. “p” is an integer of 2 to 12. R¹⁵ is a single bond or —COO—. R¹⁶ is a cyano group, an alkyl group having 1 to 6 carbon atoms, an alkoxy group having 1 to 6 carbon atoms or a phenyl group.

Examples of the liquid crystal compound having a polymerizable group represented by the above formula (5) include compounds represented by the following formulae (5-1) to (5-3), and the like.

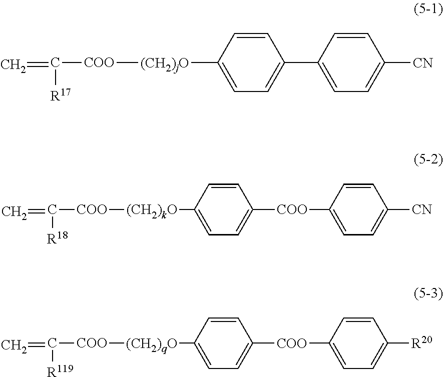

In the above formulae (5-1) to (5-3), R¹⁷, R¹⁸ and R¹⁹ each independently represent a hydrogen atom or a methyl group. j, k and q each independently represent an integer of 2 to 12. R²⁰ is an alkyl group having 1 to 6 carbon atoms or a phenyl group.

The content of the liquid crystal compound in the thermally cured type polymerizable liquid crystal composition is preferably no less than 90% by mass, more preferably 96% by mass or greater and 99.9% by mass or less, and particularly preferably 98% by mass or greater and 99.5% by mass or less. When the content of the liquid crystal compound falls within the above specific range, suitable liquid crystal responsiveness can be achieved.

As the aforementioned thermopolymerizable compound, an epoxy compound is preferred. Although the epoxy compound is not particularly limited as long as it is a compound having one or more epoxy groups in a molecule, and being cured by a reaction upon heating. However, in light of the coating property, an epoxy compound that takes a liquid state at ordinary temperatures is preferred.

The epoxy compound is exemplified by an aliphatic compound having an epoxy group, an alicyclic compound having an epoxy group, an aromatic compound having an epoxy group, and the like.

Examples of the aliphatic compound having an epoxy group include 1,4-butanediol diglycidyl ether, 1,6-hexanediol diglycidyl ether, neopentyl glycol diglycidyl ether, trimethylolpropane triglycidyl ether, polyethylene glycol diglycidyl ether, glycerin triglycidyl ether, polypropylene glycol diglycidyl ethers; polyglycidyl ethers of polyether polyol obtained by adding one, or two or more kinds of alkyleneoxides to an aliphatic polyhydric alcohol such as ethylene glycol, propylene glycol or glycerin; diglycidyl esters of aliphatic long-chain dibasic acid; monoglycidyl ethers of an aliphatic higher alcohol; glycidyl esters of a higher aliphatic acid; epoxidized soybean oil; butyl epoxystearate; octyl epoxystearate; epoxidized linseed oil; epoxidized polybutadiene, and the like.

Examples of commercially available product of the aliphatic compound having an epoxy group include SR-NPG, SR-16H, SR-PG and SR-TPG (manufactured by Sakamoto Yakuhin Kogyo Co., Ltd.); PG-202 and PG-207 (manufactured by Toto Kasei Co., Ltd.); EX-610U and EX-1610-P (Nagase ChemteX Corporation), and the like.

Examples of the alicyclic compound having an epoxy group include 3,4-epoxycyclohexylmethyl-3′,4′-epoxycyclohexanecarboxylate, 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylcyclohexanecarboxylate, ε-caprolactone-modified 3,4-epoxycyclohexylmethyl-3′,4′-epoxycyclohexanecarboxylate, trimethyl caprolactone-modified 3,4-epoxycyclohexylmethyl-3′,4′-epoxycyclohexanecarboxylate, β-methyl-δ-valerolactone-modified 3,4-epoxycyclohexylmethyl-3′,4′-epoxycyclohexanecarboxylate, methylene bis(3,4-epoxycyclohexane), di(3,4-epoxycyclohexylmethyl)ether of ethylene glycol, ethylene bis(3,4-epoxycyclohexanecarboxylate), dioctylepoxyhexahydrophthalate, di-2-ethylhexylepoxyhexahydrophthalate, and the like.

Examples of commercially available product of the alicyclic compound having an epoxy group include Celoxide 2021, Celoxide 2021P, Celoxide 2081, Celoxide 2083, Celoxide 2085, Epolead GT-300, Epolead GT-301, Epolead GT-302, Epolead GT-400, Epolead 401 and Epolead 403 (manufactured by Daicel Chemical Industries, Ltd.), and the like.

Examples of the aromatic compound having an epoxy group include compounds having an aromatic ring structure in the main skeleton, and also having two or more epoxy groups, and the like. Examples of the aromatic ring structure of such a compound include a bisphenol A type structure, a bisphenol F type structure, a novolak type structure, a naphthalene skeleton, an anthracene skeleton structure, a fluorine skeleton, and the like.

Examples of commercially available product of the aromatic compound having an epoxy group include JER806, JER828 and YL980 (manufactured by Japan Epoxy Resins Co. Ltd.); YD-127, YD-128, YDF-170, YDF-175S, YDPN-638 and YDCN-701 (manufactured by Toto Kasei Co., Ltd.); EPICLON 830, EPICLON 850, EPICLON 835 and EPICLON HP-4032D (manufactured by DIC), and the like.

In addition thereto, an epoxy compound having a (meth)acryloyl group or a vinyl group may be also used. For example, glycidyl (meth)acrylate, glycidyl α-ethylacrylate, glycidyl α-n-propylacrylate, glycidyl α-n-butylacrylate, 3,4-epoxybutyl (meth)acrylate, 3,4-epoxybutyl α-ethylacrylate, 6,7-epoxyheptyl (meth)acrylate, 6,7-epoxyheptyl α-ethylacrylate, p-vinylbenzylglycidyl ether, 3-methyl-3-(meth)acryloyloxymethyloxetane, 3-ethyl-3-(meth)acryloyloxymethyloxetane, and the like may be included.

As the epoxy compound, an aromatic compound having an epoxy group is preferred.

The content of the epoxy compound is preferably 0.1% by mass or greater and 10% by mass or less, and more preferably 0.3% by mass or greater and 3% by mass or less. When the content of the epoxy compound falls within the above specific range, suitable liquid crystal responsiveness can be achieved.

### [Photocured Polymerizable Liquid Crystal Composition]

The photocured type polymerizable liquid crystal composition is exemplified by a composition containing a polymerizable liquid crystal compound and a photopolymerization initiator (hereinafter, may also referred to as “photocured type polymerizable liquid crystal composition A”), a composition containing a liquid crystal compound, a photopolymerizable compound and a photopolymerization initiator (hereinafter, may also referred to as “photocured type polymerizable liquid crystal composition B”), and the like. It is to be noted that in the photocured type polymerizable liquid crystal composition B the liquid crystal compound may be either polymerizable or not. In addition to the foregoing, for example, a composition in which photocured type polymerizable liquid crystal compositions A and B were mixed, and the like may be also used. It should be noted that “light” for photocuring may be not only visible light, but may involve ultraviolet ray, far ultraviolet ray and the like.

As the polymerizable liquid crystal compound in the photocured type polymerizable liquid crystal composition A, and as the liquid crystal compound in the photocured type polymerizable liquid crystal composition B, those illustratively described in connection with the thermally cured type polymerizable liquid crystal composition above may be included.

The content of the liquid crystal compound (also including the polymerizable liquid crystal compound) in the photocured type polymerizable liquid crystal composition is preferably no less than 60% by mass, and more preferably 70% by mass or greater and 99.5% by mass or less, in light of curability of the resultant liquid crystal layer.

Examples of the photopolymerization initiator include 2-hydroxy-2-methyl-1-phenylpropan-1-one (manufactured by Merck & Co., Inc., Darocure 1173), 1-hydroxycyclohexyl phenyl ketone (manufactured by Ciba-Geigy Co., IRGACURE 184), 1-(4-isopropylphenyl)-2-hydroxy-2-methylpropan-1-one (manufactured by Merck & Co., Inc., Darocure 1116), 2,2-dimethoxy-1,2-diphenylethan-1-one (manufactured by Ciba-Geigy Co., IRGACURE 651), 2-methyl-1-[4-(methylthio)phenyl]-2-morpholinopropanone-1 (manufactured by Ciba-Geigy Co., IRGACURE 907), a mixture of 2,4-diethylthioxanthone (manufactured by Nippon Kayaku Co., Ltd., Kayacure DETX) with ethyl p-dimethylaminobenzoate (manufactured by Nippon Kayaku Co., Ltd., Kayacure-EPA), a mixture of isopropylthioxanthone (manufactured by Ward Blenkinsop Corp., Quantacure ITX) with ethyl p-dimethylaminobenzoate, and the like.

The content of the photopolymerization initiator is preferably 0.1% by mass or greater and 10% by mass or less in light of curability of the liquid crystal layer.

The photopolymerizable compound used in the photocured type polymerizable liquid crystal composition B has as a polymerizable group a vinyl group, a (meth)acryl group, a (meth)acryloyl group, a (meth)acrylamide group, a styryl group or the like.

Examples of the photopolymerizable compound include divinylbenzene such as styrene, chlorostyrene and α-methylstyrene; acrylate, methacrylate or fumarate having as a substituent a methyl group, an ethyl group, a propyl group, a butyl group, an amyl group, a 2-ethylhexyl group, an octyl group, a nonyl group, a dodecyl group, a hexadecyl group, an octadecyl group, a cyclohexyl group, a benzyl group, a methoxyethyl group, a butoxyethyl group, a phenoxyethyl group, an allyl group, a methallyl group, a glycidyl group, a 2-hydroxyethyl group, a 2-hydroxypropyl group, a 3-chloro-2-hydroxypropyl group, a dimethylamino ethyl group, a diethyl aminoethyl group or the like; mono(meth)acrylate or poly(meth)acrylate of ethylene glycol, polyethylene glycol, propylene glycol, polypropylene glycol, 1,3-butylene glycol, tetramethylene glycol, hexamethylene glycol, neopentyl glycol, trimethylolpropane, glycerin, pentaerythritol and the like; vinyl acetate, vinyl butyrate, vinyl benzoate, acrylonitrile, cetylvinyl ether, limonene, cyclohexene, diallyl phthalate, diallyl isophthalate, vinylpyridine, acrylic acid, methacrylic acid, acrylamide, methacrylamide, N-hydroxymethylacrylamide or N-hydroxyethylmethacrylamide, and alkyl ether compounds thereof; di(meth)acrylate of a diol prepared by adding to 1 mol of neopentyl glycol at least 2 mol or more of ethylene oxide or propyleneoxide; di or tri(meth)acrylate of triol prepared by adding to 1 mol of trimethylolpropane at least 3 mol or more of ethylene oxide or propyleneoxide; di(meth)acrylate of diol prepared by adding to 1 mol of bisphenol A at least 2 mol or more of ethylene oxide or propyleneoxide; a reaction product of 1 mol of 2-hydroxyethyl (meth)acrylate with 1 mol of phenylisocyanate or n-butylisocyanate; poly(meth)acrylate of dipentaerythritol; oligomers of caprolactone-modified hydroxypivalic acid ester neopentyl glycol diacrylate or the like, and the like.

The content of the photopolymerizable compound is preferably 3% by mass or greater and 40% by mass or less, and more preferably 10% by mass or greater and 30% by mass or less in light of curability of the resultant liquid crystal layer.

The photocured type polymerizable liquid crystal composition may contain as other component, for example, a polymerization inhibitor, and the like. Examples of the polymerization inhibitor include hydroquinonemonomethyl ether (metoquinone), hydroquinone, p-benzoquinone, phenothiazone, mono-t-butylhydroquinone, catechol, p-t-butylcatechol, benzoquinone, 2.5-di-t-butylhydroquinone, anthraquinone, 2.6-di-t-butylhydroxytoluene, and the like.

### <Method for Forming Interlayer Insulating Film>

The method for forming an interlayer insulating film for a liquid crystal display element of the present invention has the steps of:

(1) forming a coated film of the positive type radiation sensitive composition on a substrate;

(2) irradiating at least a part of the coated film formed in the step (1) with a radioactive ray;

(3) developing the coated film irradiated with a radioactive ray in the step (2); and

(4) heating the coated film developed in the step (3).

The method for forming is suited as a formation method of an interlayer insulating film for a liquid crystal display element in which a liquid crystal layer is formed by heat or light irradiation. The interlayer insulating film of the liquid crystal display element of the present invention is formed using the aforementioned positive type radiation sensitive composition. The interlayer insulating film can be, as described above, suitably used as an interlayer insulating film for a liquid crystal display element in which a liquid crystal layer is formed by heat or light irradiation.

### [Step (1)]

In the step (1), after the positive type radiation sensitive composition or a solution or dispersion liquid of the same is coated on a substrate, the solvent is removed by preferably heating (prebaking) the coated surface to from a coated film.

As a coating method of the solution or the dispersion liquid of the positive type radiation sensitive composition, an appropriate method such as, for example, a spray coating method, a roll coating method, a spin coat method, a slit die coating method, a bar coating method or the like may be adopted. Of these coating methods, a spin coating method and a slit die coating method are preferred.

Although conditions for the prebaking may vary depending on the type of each component, blend ratio and the like, the prebaking may be carried out preferably at 60° C. to 120° C. for about 1 min to 10 min. According to thus formed composition, superior pattern formability can be achieved even when prebaking conditions involved comparatively low temperatures of, for example, 60° C. to 80° C.

### <Step (2)>

In the step (2), at least a part of the coated film thus formed is subjected to exposure. In this case, when a part of the coated film is exposed, the exposure is commonly carried out through a photomask having a certain pattern. As a radioactive ray used in the exposure, a radioactive ray employed for the photoacid generator is suitable. Among these radioactive rays, those having a wavelength falling within the range of 190 nm to 450 nm are preferred, and radioactive rays including an ultraviolet ray of 365 nm are particularly preferred.

The exposure amount is preferably 500 J/m² to 6,000 J/m², and more preferably 1,500 J/m² to 1,800 J/m² as a measurement of intensity of the radioactive ray at a wavelength of 365 nm determined using an illuminometer (OAI model 356, OAI Optical Associates).

### <Step (3)>

In the step (3), a certain pattern is formed by developing the coated film after exposure to remove unwanted portions (irradiated portions with the radioactive ray). A developing solution used in the development step is preferably an aqueous alkaline solution. Examples of the alkali include: inorganic alkali such as sodium hydroxide, potassium hydroxide, sodium carbonate, sodium silicate, sodium metasilicate, and ammonia; quaternary ammonium salts such as tetramethylammonium hydroxide, and tetraethylammonium hydroxide, and the like.

The aqueous alkali solution may be used after adding a water soluble organic solvent such as methanol or ethanol, and a surfactant in an appropriate amount. The concentration of alkali in the aqueous alkali solution is preferably 0.1% by mass or greater and 5% by mass or less in light of possibility to achieve adequate developability. The development method is exemplified by a puddle method, a dipping method, an immersion swing method, a showering method, and the like. The development time may vary depending on the constitution of the positive type radiation sensitive composition, but is preferably for about 10 sec to 180 sec. It is to be noted that the positive type radiation sensitive composition enables a stable pattern to be formed even if the development time is somewhat prolonged or shortened, without influences of such a time variation. Subsequently to such a development step, washing with, for example, running water for 30 sec to 90 sec, followed by air drying with, for example, compressed air or compressed nitrogen enables a desired pattern to be formed.

### <Step (4)>

In the step (4), a cured product can be obtained by heating the patterned thin film using a heating apparatus such as a hot plate or an oven to accelerate the curing reaction of the polymer (A). The heating temperature is, for example, 120° C. to 250° C. The heating time may vary depending on the type of the heating appliance, but, for example, is 5 min to 30 min when the heating step is carried out on a hot plate, and is 30 min to 90 min when the heating step is carried out in an oven. A step baking method in which the heating step is carried out two or more times, or the like may be also used. In this manner, a patterned thin film corresponding to the intended interlayer insulating film or the like can be formed on the surface of the substrate.

Thus formed interlayer insulating film has a film thickness of preferably 0.1 μm to 8 μm, more preferably 0.1 μm to 6 μm, and particularly preferably 0.1 μm to 4 μm.

### <Liquid Crystal Display Element>

Accordingly the liquid crystal display element of the present invention comprises two substrates disposed oppositely, an interlayer insulating film laminated on the inner face side of at least any of the substrates, and a liquid crystal layer being provided between the substrates, and thus a liquid crystal cell is configured. Both two faces of this liquid crystal cell, i.e., the external side of both two substrates are provided with a polarizing plate, in general. It is to be noted that of the two polarizing plates, one may be replaced with a reflecting plate. Also, the liquid crystal display element may be further provided with, for example, a microcolor filter or the like as other constitutive element.

The liquid crystal display element may be used in monitoring devices for television sets or personal computers and various types of liquid crystal display devices of mobile phones, gaming hardwares, and the like.

### <Method for Producing Liquid Crystal Display Element>

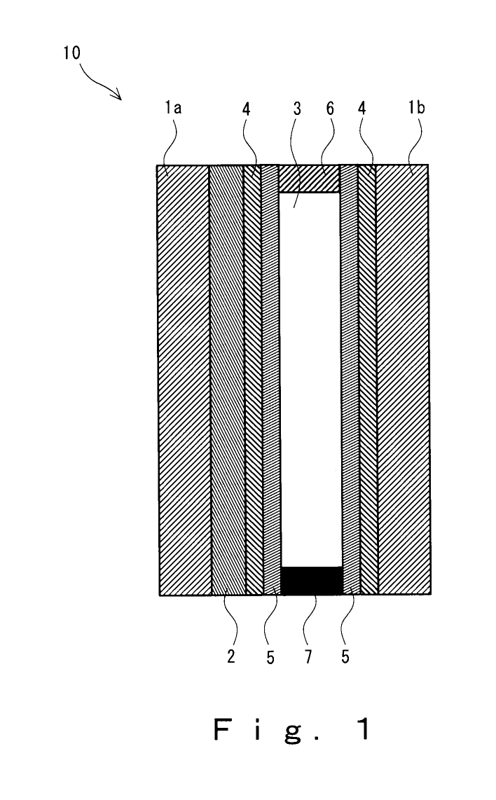

As a method for producing a liquid crystal display element, for example, a well-known production method of a liquid crystal display element may be used, in which a PSA technique is used. One example of the production method is explained with reference to FIG. 1. A liquid crystal display element (liquid crystal cell) 10 during the course of production shown in FIG. 1 is provided with principally two substrates 1a and 1b disposed oppositely, an interlayer insulating film 2 laminated on the inner face side of the substrate 1a, and a liquid crystal layer 3 provided between the substrates 1a and 1b.

First, the interlayer insulating film 2 is formed on the surface of the substrate 1a by the method described above. Next, a transparent electrode film 4 is formed on the surface of the interlayer insulating film 2 and the substrate 1b, and further a liquid crystal alignment film 5 is formed on the surface of each transparent electrode film 4. Two substrates 1a and 1b are parallelly disposed with the side of the liquid crystal alignment film 5 inside, and these are laminated with a sealing material 6 to produce a cell. In this procedure, a part of the sealing material 6 is not laminated to provide an injection hole 7. After the polymerizable liquid crystal composition is injected into the cell from the injection hole 7 and the injection hole 7 for filling the composition is sealed, the liquid crystal layer 3 is formed by heating or irradiation with light to obtain a liquid crystal cell (the state of the liquid crystal display element 10 FIG. 1 during the course of production). A liquid crystal display element is obtained by laminating a polarizing plate on both two faces of this liquid crystal cell.

The transparent conductive film 4 is exemplified by a NESA film (manufactured by PPG, USA, registered trademark) constituted with tin oxide (SnO₂), an ITO film constituted with indium oxide-tin oxide (In₂O₃—SnO₂), and the like. The method for obtaining a patterned transparent conductive film may include, for example: a method in which after forming a transparent conductive film not being patterned, a pattern is formed by photoetching; a method in which a mask having a desired pattern is used in forming a transparent conductive film, and the like.

The method for forming the liquid crystal alignment films 5 are exemplified by a method in which a composition for forming a liquid crystal alignment film is each coated by preferably a printing method, a spinner method or an ink jet method, and then each coated surface is heated to form a coated film. As the composition for forming a liquid crystal alignment film, for example, a polyimide aligning agent or the like may be used. By subjecting the coated film after heating to a rubbing treatment, liquid crystal compound aligning capabilities are imparted to the coated film, whereby the liquid crystal alignment film 5 is formed.

The polymerizable liquid crystal composition is injected between the substrates having the liquid crystal alignment film 5 formed as described above, and a voltage is applied to allow the liquid crystal compound to be tilted. In this state, heating or light irradiation is carried out to permit curing of the polymerizable liquid crystal composition. In this procedure, when the coated film is subjected to a rubbing treatment, two substrates 1a and 1b will be oppositely disposed such that the rubbing direction on each coated film forms a certain angle with one another such as, for example, to be orthogonal or antiparallel.

The heating time is preferably 10 min or greater and 60 min or less in the case in which the polymerizable liquid crystal composition is thermally cured. Also, the heating temperature is preferably 150° C. or greater and 300° C. or less. When the heating time or temperature is out of the aforementioned specific range, sufficient polymerization fails, and thus the resultant liquid crystal layer may have deteriorated responsiveness. On the other hand, when the heating time or temperature is beyond the aforementioned upper limit, the interlayer insulating film and the like may be deformed.

In the case in which the polymerizable liquid crystal composition is photocured, the type of the light is preferably an ultraviolet ray. Also, the amount of radiation of the light is preferably 50 mJ/cm² or greater and 400 mJ/cm² or less. When the amount of radiation is less than the above lower limit, sufficient polymerization fails, and thus the resultant liquid crystal layer may have deteriorated responsiveness. On the other hand, when the amount of irradiation is beyond the above upper limit, deformation of the interlayer insulating film and the like may occur.

Accordingly, liquid crystal display element can be obtained by thus laminating a polarizing plate on the surface of the external side of the liquid crystal cell after forming the liquid crystal layer 3.

According to the liquid crystal display element produced in this manner, superior heat resistance and light resistance can be provided even if the liquid crystal layer is formed with heating or light irradiation since the interlayer insulating film is formed from a positive type radiation sensitive composition containing the polymer (A) having a particular structure unit. Therefore, the liquid crystal display element achieves high production efficiency owing to less deformation which may occur during the production steps, and attaining a high voltage holding ratio is enabled.

### EXAMPLES

Hereinafter, the present invention is explained in detail by way of Examples, but Example the present invention should not be construed as being limited based on the disclosures of Examples.

The Mw and Mn of the polymer were determined by GPC according to the following conditions.

apparatus: GPC-101 (manufactured by Showa Denko K.K.)

column: GPC-KF-801, GPC-KF-802, GPC-KF-803 and GPC-KF-804, which were connected

mobile phase: tetrahydrofuran

column temperature: 40° C.

flow rate: 1.0 mL/min

sample concentration: 1.0% by mass

amount of injected sample: 100 μL

detector: differential thermal analyzer

standard substance: mono-dispersed polystyrene

### <Preparation of Polymerizable Liquid Crystal Composition>

### Preparation Example 1

A liquid crystal composition (i) was obtained by blending each liquid crystal compound (liquid crystal compound represented by the above formula (a): 25%; liquid crystal compound represented by the formula (b): 30% by mass; liquid crystal compound represented by the formula (c): 30% by mass; and liquid crystal compound represented by the formula (d): 15% by mass). This liquid crystal composition (i) in an amount of 99 parts by mass, and 1 part by mass of trimethylolpropanetriglycidyl ether as a thermopolymerizable compound were blended to obtain a thermally cured type polymerizable liquid crystal composition (I).

### Preparation Example 2

A polymerizable liquid crystal composition (ii) was obtained by blending each polymerizable liquid crystal compound represented by the following formula (liquid crystal compound represented by the following formula (e): 47.5% by mass; liquid crystal compound represented by the formula (f): 47.5% by mass; and liquid crystal compound represented by the formula (g): 5.0% by mass). This polymerizable liquid crystal composition (ii) in an amount of 99 parts by mass, and 1 part by mass of 2,2-dimethoxy-1,2-diphenylethan-1-one (manufactured by Ciba-Geigy Co., IRGACURE 651) as a photopolymerization initiator were blended to obtain a photocured type polymerizable liquid crystal composition (II).

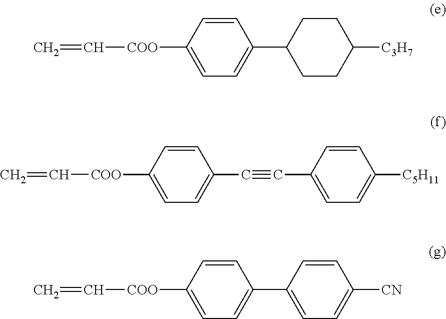

### Preparation Example 3

The liquid crystal composition (i) in an amount of 80 parts by mass, 19 parts by mass of caprolactone-modified hydroxypivalic acid ester neopentyl glycol diacrylate (manufactured by Nippon Kayaku Co., Ltd., KAYARAD HX620) as a photopolymerizable compound, and 1 part by mass of benzyldimethyl ketal (manufactured by Ciba-Geigy Co., IRGACURE 651) as a photopolymerization initiator were blended to obtain a photocured type polymerizable liquid crystal composition (III).

### <Synthesis of Polymer (A)>

### Synthesis Example 1

To a flask equipped with a condenser and a stirrer, were charged 7 parts by mass of 2,2′-azobis(2,4-dimethylvaleronitrile), and 200 parts by mass of diethylene glycol ethylmethyl ether. Subsequently, 5 parts by mass of methacrylic acid, 40 parts by mass of 1-ethoxyethyl methacrylate, 5 parts by mass of styrene, 40 parts by mass of glycidyl methacrylate, 10 parts by mass of 2-hydroxyethyl methacrylate and 3 parts by mass of an α-methylstyrene dimer were charged, and nitrogen substitution was carried out, followed by starting gentle stirring. The temperature of the solution was elevated to 70° C., and this temperature was kept for 5 hrs to obtain a polymer solution containing a polymer (A-1). The polymer (A-1) had a weight average molecular weight (Mw) in terms of the polystyrene equivalent of 9,000. Also, the solid content of the polymer solution obtained in this procedure was 32.1% by mass.

### Synthesis Example 2

To a flask equipped with a condenser and a stirrer, were charged 7 parts by mass of 2,2′-azobis(2,4-dimethylvaleronitrile), and 200 parts by mass of diethylene glycol ethylmethyl ether. Subsequently, 5 parts by mass of methacrylic acid, 40 parts by mass of tetrahydro-2H-pyran-2-yl methacrylate, 5 parts by mass of styrene, 40 parts by mass of glycidyl methacrylate, 10 parts by mass of 2-hydroxyethyl methacrylate and 3 parts by mass of an α-methylstyrene dimer were charged, and nitrogen substitution was carried out, followed by starting gentle stirring. The temperature of the solution was elevated to 70° C., and this temperature was kept for 5 hrs to obtain a polymer solution containing a polymer (A-2). The polymer (A-2) had a weight average molecular weight (Mw) in terms of the polystyrene equivalent of 9,000. Also, the solid content of the polymer solution obtained in this procedure was 31.3% by mass.

### Synthesis Example 3

To a flask equipped with a condenser and a stirrer, were charged 7 parts by mass of 2,2′-azobis(2-methylpropionate methyl), and 200 parts by mass of propylene glycol monomethyl ether acetate. Subsequently, 67 parts by mass of 1-n-butoxyethyl methacrylate, 23 parts by mass of benzyl methacrylate and 10 parts by mass of methacrylic acid were charged, and nitrogen substitution was carried out, followed by starting gentle stirring. The temperature of the solution was elevated to 80° C., and this temperature was kept for 6 hrs to obtain a polymer solution containing a polymer (A-3). The polymer (A-3) had a weight average molecular weight (Mw) in terms of the polystyrene equivalent of 9,000. Also, the solid content of the polymer solution obtained in this procedure was 30.3% by mass.

### Synthesis Example 4

To a flask equipped with a condenser and a stirrer, were charged 7 parts by mass of 2,2′-azobis(2-methylpropionate methyl), and 200 parts by mass of propylene glycol monomethyl ether acetate. Subsequently, 90 parts by mass of 1-benzyloxyethyl methacrylate, 6 parts by mass of 2-hydroxyethyl methacrylate and 4 parts by mass of methacrylic acid were charged, and nitrogen substitution was carried out, followed by starting gentle stirring. The temperature of the solution was elevated to 80° C., and this temperature was kept for 6 hrs to obtain a polymer solution containing a polymer (A-4). The polymer (A-4) had a weight average molecular weight (Mw) in terms of the polystyrene equivalent of 9,000. Also, the solid content of the polymer solution obtained in this procedure was 31.2% by mass.

### Synthesis Example 5

To a flask equipped with a condenser and a stirrer, were charged 7 parts by mass of 2,2′-azobis(2-methylpropionate methyl), and 200 parts by mass of propylene glycol monomethyl ether acetate. Subsequently, 85 parts by mass of tetrahydro-2H-pyran-2-yl methacrylate, 7 parts by mass of 2-hydroxyethyl methacrylate and 8 parts by mass of methacrylic acid were charged, and nitrogen substitution was carried out, followed by starting gentle stirring. The temperature of the solution was elevated to 80° C., and this temperature was kept for 6 hrs to obtain a polymer solution containing a polymer (A-5). The polymer (A-5) had a weight average molecular weight (Mw) in terms of the polystyrene equivalent of 10,000. Also, the solid content of the polymer solution obtained in this procedure was 29.2% by mass.

### Synthesis Example 6

To a flask equipped with a condenser and a stirrer, were charged 7 parts by mass of 2,2′-azobis(2,4-dimethylvaleronitrile), and 200 parts by mass of diethylene glycol ethylmethyl ether. Subsequently, 52 parts by mass of glycidyl methacrylate and 48 parts by mass of benzyl methacrylate were charged, and nitrogen substitution was carried out, followed by starting gentle stirring. The temperature of the solution was elevated to 80° C., and this temperature was kept for 6 hrs to obtain a polymer solution containing a polymer (A-6). The polymer (A-6) had a weight average molecular weight (Mw) in terms of the polystyrene equivalent of 10,000. Also, the solid content of the polymer solution obtained in this procedure was 32.3% by mass.

### Synthesis Example 7

To a flask equipped with a condenser and a stirrer, were charged 7 parts by mass of 2,2′-azobis(2,4-dimethylvaleronitrile), and 200 parts by mass of diethylene glycol ethylmethyl ether. Subsequently, 45 parts by mass of 3,4-epoxycyclohexylmethyl methacrylate, 45 parts by mass of benzyl methacrylate and 10 parts by mass of methacrylic acid were charged, and nitrogen substitution was carried out, followed by starting gentle stirring. The temperature of the solution was elevated to 80° C., and this temperature was kept for 6 hrs to obtain a polymer solution containing a polymer (A-7). The polymer (A-7) had a weight average molecular weight (Mw) in terms of the polystyrene equivalent of 10,000. Also, the solid content of the polymer solution obtained in this procedure was 33.2% by mass.

### Synthesis Example 8

To a flask equipped with a condenser and a stirrer, were charged 7 parts by mass of 2,2′-azobis(2,4-dimethylvaleronitrile), and 200 parts by mass of diethylene glycol ethylmethyl ether. Subsequently, 35 parts by mass of 1-n-butoxyethyl methacrylate, 35 parts by mass of benzyl methacrylate and 30 parts by mass of glycidyl methacrylate were charged, and nitrogen substitution was carried out, followed by starting gentle stirring. The temperature of the solution was elevated to 80° C., and this temperature was kept for 6 hrs to obtain a polymer solution containing a polymer (A-8). The polymer (A-8) had a weight average molecular weight (Mw) in terms of the polystyrene equivalent of 10,000. Also, the solid content of the polymer solution obtained in this procedure was 32.3% by mass.

### Synthesis Example 9

To a flask equipped with a condenser and a stirrer, were charged 7 parts by mass of 2,2′-azobis-(2,4-dimethylvaleronitrile), and 200 parts by mass of diethylene glycol ethylmethyl ether. Subsequently, 16 parts by mass of methacrylic acid, 16 parts by mass of tricyclo[5.2.1.0^{2,6}]decan-8-yl methacrylate, 20 parts by mass of benzyl methacrylate, 40 parts by mass of glycidyl methacrylate, 10 parts by mass of styrene and 3 parts by mass of α-methylstyrene dimer were charged, and nitrogen substitution was carried out, followed by starting gentle stirring. The temperature of the solution was elevated to 70° C., and this temperature was kept for 4 hrs to obtain a polymer solution containing a polymer (CA-1). The polymer (CA-1) had a weight average molecular weight (Mw) in terms of the polystyrene equivalent of 9,000 and a molecular weight distribution (Mw/Mn) of 2.2. Also, the solid content of the polymer solution obtained in this procedure was 33.4% by mass.

### <Preparation of Positive Type Radiation Sensitive Composition>

### Example 1

A solution containing the polymer (A-1) obtained in Synthesis Example 1 (amount corresponding to 100 parts by mass (solid content) of the polymer (A-1)) was mixed with 3 parts by mass of (5-propylsulfonyloxyimino-5H-thiophen-2-ylidene)-(2-methylphenyl)acetonitrile (manufactured by Ciba Specialty Chemicals Corp., IRGACURE PAG 103) as a photoacid generator (B), diethylene glycol ethylmethyl ether as the organic solvent (C), 0.1 parts by mass of a silicone based surfactant (manufactured by Dow Corning Toray Co., Ltd., SH 8400 FLUID) as the surfactant (D), and the mixture was filtrated with a membrane filter having a pore size of 0.2 μm to prepare a positive type radiation sensitive composition (S-1).

### Examples 2 to 5, and Comparative Example 1

Positive type radiation sensitive compositions of Examples 2 to 5, and Comparative Example 1 were prepared by a similar operation to Example 1 except that the component (A) of the type and the amount as shown in Table 1 was used. It should be noted that “-” in the column indicates that the corresponding component was not used.

### <Production of Liquid Crystal Cell>

### Example 6

### [Production of Transparent Electrode Film/Interlayer Insulating Film/Glass Substrate]

On a 10×10 cm glass substrate having a SiO₂ film formed for preventing elution of sodium ion on the surface, the positive type radiation sensitive composition (S-1) was coated with a spin coater, and a coated film having a film thickness of 2.0 μm was formed by prebaking at 90° C. for 10 min. Subsequently, Aligner (manufactured by Canon, Inc., MPA-600FA) was used to carry out exposure of the coating film. Next, an interlayer insulating film was formed on the glass substrate by postbaking at 230° C. for 30 min.

Then, a transparent electrode (ITO electrode) film was formed on thus obtained interlayer insulating film according to the following procedure. ITO sputtering was performed with a high speed sputtering apparatus (manufactured by ULVAC Japan, Ltd., SH-550-C12) using an ITO target (ITO filling factor: no less than 95%; In₂O₃/SnO₂=90/10 mass ratio) at 60° C. In this process, the atmosphere involved a pressure of 1.0×10⁻⁵ Pa, an Ar gas flow rate of 3.12×10⁻³ m³/Hr, an O₂ gas flow rate of 1.2×10⁻⁵ m³/Hr. The substrate after sputtering was heated in a clean oven at 240° C. for 60 min, to execute annealing.

### [Production of Transparent Electrode Film/Glass Substrate]

On a 10×10 cm glass having a SiO₂ film formed for preventing elution of sodium ion on the surface, ITO sputtering was performed with the aforementioned high speed sputtering apparatus using an ITO target (ITO filling factor: no less than 95%; In₂O₃/SnO₂=90/10 mass ratio) at 60° C. In this process, the atmosphere involved a pressure of 1.0×10⁻⁵ Pa, an Ar gas flow rate of 3.12×10⁻³ m³/Hr, an O₂ gas flow rate of 1.2×10⁻⁵ m³/Hr. The substrate after sputtering was heated in a clean oven at 240° C. for 60 min, to execute annealing.

### [Formation of Liquid Crystal Alignment Film]

On the surface the transparent electrode having each one of: transparent electrode film/interlayer insulating film/glass substrate and transparent electrode film/glass substrate produced according to the above procedure, a polyimide aligning agent (AL-1254, manufactured by JSR) was spin coated. This substrate was maintained at 180° C. for 80 min to form a polyimide film on the substrate. This polyimide film was subjected to a rubbing treatment to produce an aligned glass substrate.

### [Production of Cell]

Two pieces of each glass substrate aligned as described above were disposed oppositely such that aligned faces were opposed, and laminated with a sealing material with which 0.8 mm glass beads were mixed to produce a cell.

### [Formation of Liquid Crystal Layer]

The polymerizable liquid crystal composition (I) was injected into the cell, and heated in a clean oven at 230° C. for 30 min to obtain a liquid crystal cell of Example 6.

### Examples 7 to 20 and Comparative Examples 2 to 4

Liquid crystal cells of Examples 7 to 20 and Comparative Examples 2 to 4 were obtained by a similar operation to Example 6 except that the types of the positive type radiation sensitive composition and the polymerizable liquid crystal composition shown in Table 2 were used. It is to be noted that when the photocured type polymerizable liquid crystal composition (II) or (III) was used as a polymerizable liquid crystal composition, ultraviolet ray was in the amount of light of 160 mJ/cm² was irradiated using an ultraviolet ray lamp at room temperature, in place of heating in a clean oven at 230° C. for 30 min to obtain liquid crystal cells.

### <Evaluation>

With respect to the positive type radiation sensitive compositions of Examples 1 to 5 and Comparative Example 1, and liquid crystal cells of Examples 6 to 20 and Comparative Examples 2 to 4, each of the characteristics were evaluated. The evaluation results are shown in Table 1 and Table 2 in all.

### [Storage Stability]

The positive type radiation sensitive resin composition was left to stand in an oven at 40° C. for one week, and the viscosity was measured before and after placing into the oven to determine the rate of change of viscosity. In this test, when the rate of change of viscosity is less than 5%, the storage stability may be considered as favorable, whereas when the rate of change of viscosity is no less than 5%, the storage stability may be considered as unfavorable.

### [Voltage Holding Ratio]

The liquid crystal cell was place into a thermostatic chamber at 60° C., and the voltage holding ratio was determined with a liquid crystal voltage holding ratio measurement system (manufactured by TOYO Corporation, model HR-1A). In this test, voltage applied was 5.5 V with a square wave, and the measurement frequency was 60 Hz. The voltage holding ratio (%) herein means a value determined by:

Potential difference of the liquid crystal cell after 16.7 milisec/voltage applied at 0 milisec)×100(%). The voltage holding ratio of the liquid crystal cell being no greater than 90% indicates failure of the liquid crystal cell in holding the applied voltage at a certain level for a time period of 16.7 milisec, suggesting the possibility of influences on reliability of the liquid crystal display panel. Additionally, it is highly probable that display faults such as after image may be caused.

TABLE 1

| | | | | | | | Comparative |
|---|---|---|---|---|---|---|---|
| Composition | | Ex. 1 | Ex. 2 | Ex. 3 | Ex. 4 | Ex. 5 | Ex. 1 |
| (parts by mass) | | S-1 | S-2 | S-3 | S-4 | S-5 | CS-1 |
| polymer (A) | A-1 | 100 | — | — | — | — | — |
| | A-2 | — | 100 | — | — | — | — |
| | A-3 | — | — | 50 | — | — | — |
| | A-4 | — | — | — | 50 | — | — |
| | A-5 | — | — | — | — | 50 | — |
| | A-6 | — | — | 50 | — | — | — |
| | A-7 | — | — | — | 50 | — | — |
| | A-8 | — | — | — | — | 50 | — |
| Comparative | CA-1 | — | — | — | — | — | 100 |
| component of | | | | | | | |
| polymer (A) | | | | | | | |

| | | | | | | |
|---|---|---|---|---|---|---|
| Storage stability (%) | 3 | 3 | 3 | 3 | 3 | 10 |

TABLE 2

| | | | | | | | | | | | | | | | | Com- | Com- | Com- |
|---|---|---|---|---|---|---|---|---|---|---|---|---|---|---|---|---|---|---|
| | | | | | | | | | | | | | | | | para- | para- | para- |
| | Ex. | Ex. | Ex. | Ex. | Ex. | Ex. | Ex. | Ex. | Ex. | Ex. | Ex. | Ex. | Ex. | Ex. | Ex. | tive | tive | tive |
| | 6 | 7 | 8 | 9 | 10 | 11 | 12 | 13 | 14 | 15 | 16 | 17 | 18 | 19 | 20 | Ex. 2 | Ex. 3 | Ex. 4 |
| Positive type | S-1 | S-1 | S-1 | S-2 | S-2 | S-2 | S-3 | S-3 | S-3 | S-4 | S-4 | S-4 | S-5 | S-5 | S-5 | s-1 | s-1 | s-1 |
| radiation | | | | | | | | | | | | | | | | | | |
| sensitive | | | | | | | | | | | | | | | | | | |
| composition | | | | | | | | | | | | | | | | | | |
| Polymerizable | I | II | III | I | II | III | I | II | III | I | II | III | I | II | III | I | II | III |
| liquid crystal | | | | | | | | | | | | | | | | | | |
| composition | | | | | | | | | | | | | | | | | | |
| Voltage | 98 | 97 | 97 | 98 | 98 | 98 | 98 | 97 | 97 | 97 | 98 | 98 | 97 | 98 | 97 | 88 | 87 | 86 |
| holding | | | | | | | | | | | | | | | | | | |
| ratio(%) | | | | | | | | | | | | | | | | | | |

From the results shown in Table 1, it was revealed that the positive type radiation sensitive compositions of Examples 1 to 5 had higher storage stability as compared with the composition of Comparative Example 1. In addition, from the results shown in Table 2, it was revealed that the liquid crystal cells of Examples 6 to 20 exhibited superior voltage holding ratio and are excellent in heat resistance and light resistance in the production steps in which heating or light irradiation are involved, as compared with the liquid crystal cells of Comparative Examples 2 to 4.

### INDUSTRIAL APPLICABILITY

As explained in the foregoing, since the interlayer insulating film of the liquid crystal display element of the present invention has a superior heat resistance and light resistance, deformation and the like in the production step can be suppressed, and consequently the liquid crystal display element of the present invention can achieve a superior voltage retaining capacity. In addition, since the positive type radiation sensitive composition is superior in storage stability, high productivity of the liquid crystal display element is provided.

### EXPLANATION OF THE REFERENCE SYMBOLS

10 liquid crystal display element during the course of production
1a, 1b substrate
2 interlayer insulating film
3 liquid crystal layer
4 transparent electrode film
5 liquid crystal alignment film
6 sealing material
7 injection hole

1. A liquid crystal display element comprising:
two substrates disposed oppositely,
an interlayer insulating film laminated on the inner face side of at least one of the substrates, and
a liquid crystal layer being provided between the substrates, and being formed from a polymerizable liquid crystal composition, wherein
a resin constituting the interlayer insulating film has a crosslinking moiety of a polymer represented by the following formula (1): 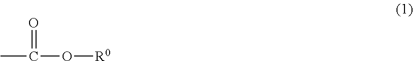
wherein, R⁰ is a group represented by the following formulae (1-1) to (1-6).

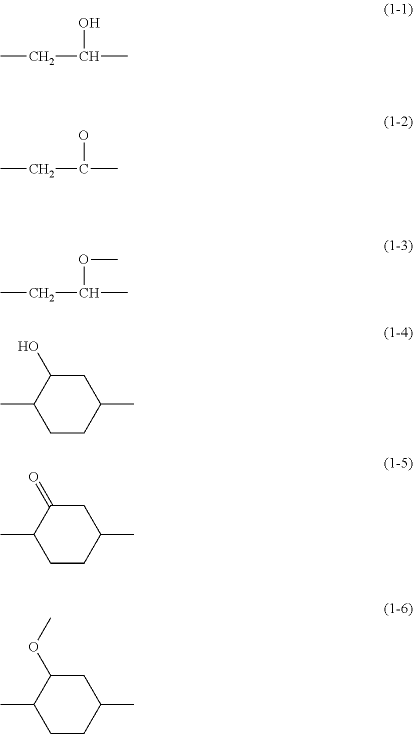

2. The liquid crystal display element according to claim 1, wherein the interlayer insulating film is formed using a positive type radiation sensitive composition comprising:
(A) a polymer having a structure unit including a group represented by the following formula (2) and an epoxy group-containing structure unit in the same or different polymer molecules;
(B) a photoacid generator; and
(C) an organic solvent. 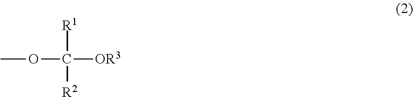
wherein, R¹ and R² each independently represent a hydrogen atom, an alkyl group, a cycloalkyl group or an aryl group, and a part or all of hydrogen atoms of the alkyl group, the cycloalkyl group or the aryl group may be substituted; both R¹ and R² are not concomitantly a hydrogen atom; R³ is an alkyl group, a cycloalkyl group, an aralkyl group, an aryl group or a group represented by -M (R^{3 m})₃, wherein M is Si, Ge or Sn; R^{3 m} is an alkyl group, and a part or all of hydrogen atoms of these groups may be substituted; and R¹ and R³ may link to form a cyclic ether.

3. A liquid crystal display element according to claim 1, wherein the polymerizable liquid crystal composition has photopolymerizability or thermal polymerizability.

4. A positive type radiation sensitive composition used for forming an interlayer insulating film of a liquid crystal display element provided with:
two substrates disposed oppositely;
an interlayer insulating film laminated on the inner face side of at least one of the substrates; and
a liquid crystal layer being provided between the substrates, and being formed from a polymerizable liquid crystal composition,
the positive type radiation sensitive composition comprising:
(A) a polymer having a structure unit including a group represented by the following formula (2) and an epoxy group-containing structure unit in the same or different polymer molecules;
(B) a photoacid generator; and
(C) an organic solvent. 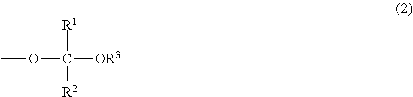
wherein, R¹ and R² each independently represent a hydrogen atom, an alkyl group, a cycloalkyl group or an aryl group, and a part or all of hydrogen atoms of the alkyl group, the cycloalkyl group or the aryl group may be substituted; both R¹ and R² are not concomitantly a hydrogen atom; R³ is an alkyl group, a cycloalkyl group, an aralkyl group, an aryl group or a group represented by -M (R^{3 m})₃, wherein M is Si, Ge or Sn; R^{3 m} is an alkyl group, and a part or all of hydrogen atoms of these groups may be substituted; and R¹ and R³ may link to form a cyclic ether.

5. The positive type radiation sensitive composition according to claim 4 further comprising (D) a surfactant, wherein this surfactant (D) is a silicone based surfactant.

6. A method for forming an interlayer insulating film for a liquid crystal display element, the method comprising:
(1) forming a coated film of the positive type radiation sensitive composition according to claim 4 on a substrate;
(2) irradiating at least a part of the coated film formed in the step (1) with a radioactive ray;
(3) developing the coated film irradiated with a radioactive ray in the step (2); and
(4) heating the coated film developed in the step (3).

7. An interlayer insulating film for a liquid crystal display element formed using the positive type radiation sensitive composition according to claim 4.
